(19) United States
(12) Patent Application Publication
(10) Pub. No.: US 2026/0162695 A1
(43) Pub. Date: Jun. 11, 2026

(54) SEMICONDUCTOR MEMORY DEVICE

(71) Applicant: SAMSUNG ELECTRONICS CO., LTD., Suwon-si (KR)

(72) Inventors: Kohji KANAMORI, Suwon-si (KR); Sehee JANG, Suwon-si (KR); Seungmin SONG, Suwon-si (KR)

(73) Assignee: SAMSUNG ELECTRONICS CO., LTD., Suwon-si (KR)

(21) Appl. No.: 19/400,619

(22) Filed: Nov. 25, 2025

(30) Foreign Application Priority Data
Dec. 11, 2024 (KR) 10-2024-0184143

(51) Int. Cl. G11C 5/06; G11C 16/04; H01L 25/18; H10B 43/10; H10B 43/27; H10B 43/35; H10B 80/00; H10D 80/30

(52) U.S. Cl. CPC G11C 5/063; G11C 16/0483; H10B 43/10; H10B 43/27; H10B 43/35; H10B 80/00; H10D 80/30; H10W 90/00; H10W 90/20; H10W 90/24; H10W 90/752; H10W 90/754

(57) ABSTRACT

A semiconductor memory device includes a mold structure including a gate electrode and a mold insulating layer stacked in a first direction, channel structures which pass through the mold structure, bit lines spaced apart from each other in one direction and connected to one of the channel structures, a cell gate contact structure which passes through at least a portion of the mold structure, overlaps with the plurality of channel structures, and is connected to the gate electrode, and a contact wiring which is spaced apart from the bit lines in the one direction, and connected to the cell gate contact structure. The bit lines include a nearest neighboring bit line which is most adjacent to the contact wiring in the one direction. A first distance between the contact wiring and the nearest neighboring bit line in the one direction is greater than a second distance between the bit lines.

### CROSS-REFERENCE TO RELATED APPLICATIONS

This application claims the benefit of Korean Patent Application No. 10-2024-0184143, filed on Dec. 11, 2024, in the Korean Intellectual Property Office, the disclosure of which is incorporated herein by reference in its entirety.

### BACKGROUND

### 1. Field of the Invention

Example embodiments relate to a semiconductor memory device.

### 2. Description of the Related Art

As the demand for semiconductor memory devices for storing large volume of data in electronic systems increases, research is being conducted on ways to increase the data storage capacity of semiconductor memory devices. One of the proposed solution to increase the data storage capacity of semiconductor memory devices is to include memory cells that are arranged in a three-dimensional structure, rather than the conventional two-dimensional arrangement of memory cells.

### SUMMARY

An aspect provides a semiconductor memory device with improved electrical characteristics and integration.

However, the goals to be achieved by example embodiments of the present disclosure are not limited to the objects described above and other objects may be clearly understood from the following description by those skilled in the art.

According to an aspect, there is provided a semiconductor memory device including a mold structure including a gate electrode and a mold insulating layer which are alternately stacked in a first direction, a plurality of channel structures which pass through the mold structure in the first direction, a cell gate contact structure which passes through at least a portion of the mold structure, overlaps with the plurality of channel structures in the second direction and the third direction, and is connected to the gate electrode, a plurality of bit lines disposed on one side of the cell gate contact structure, spaced apart from each other in a second direction crossing the first direction, extended in a third direction crossing the first direction and the second direction, and connected to at least one of the plurality of channel structures, and a contact wiring which is extended in the third direction, spaced apart from the plurality of bit lines in the second direction, and connected to the cell gate contact structure. The plurality of bit lines include first and second bit lines which are more adjacent to the contact wiring in the second direction than other bit lines among the plurality of bit lines, the first bit line is disposed between the contact wiring and the second bit line, and a first distance between the contact wiring and the first bit line in the second direction is greater than a second distance between the first bit line and the second bit line in the second direction.

According to another aspect, there is also provided a semiconductor memory device including a mold structure including a gate electrode and a mold insulating layer which are alternately stacked in a first direction, a plurality of channel structures which pass through the mold structure in the first direction, a plurality of bit lines spaced apart from each other in a second direction crossing the first direction, extended in a third direction crossing the first direction and the second direction, and connected to at least one of the plurality of channel structures, a cell gate contact structure which passes through at least a portion of the mold structure, disposed between the plurality of channel structures, and is connected to the gate electrode, and a contact wiring which is extended in the third direction, spaced apart from the plurality of bit lines in the second direction, and connected to the cell gate contact structure. The cell gate contact structure includes a plurality of contact structures spaced apart and disposed in the second direction, at least one of the plurality of bit lines is disposed between the plurality of contact structures in the second direction, and vertical levels of the plurality of bit lines and a vertical level of the contact wiring in the first direction are equal.

According to still another aspect, there is provided a semiconductor memory device including a cell structure in which a plurality of memory cells are disposed and a peripheral circuit structure disposed to the cell structure in a first direction. The cell structure includes a mold structure including a gate electrode and a mold insulating layer which are alternately stacked in the first direction, a plurality of channel structures which pass through the mold structure in the first direction and form the plurality of memory cells, a plurality of bit lines which are spaced apart from each other in a second direction crossing the first direction, extended in a third direction crossing the first direction and the second direction and connected to at least one of the plurality of channel structures, a cell gate contact structure which passes through at least a portion of the mold structure and is connected to the gate electrode, and a contact wiring which is extended in the third direction, spaced apart from the plurality of bit lines in the second direction, and connected to the cell gate contact structure. The cell structure includes a first cell region and a second cell region in which the cell gate contact structure is disposed and which do not overlap with each other in the second direction. The peripheral circuit structure includes a first peripheral circuit region which overlaps with the first cell region in the first direction, a second peripheral circuit region which overlaps with the second cell region in the first direction, a third peripheral circuit region which is disposed in the second direction with the first peripheral circuit region and is disposed in the third direction with the second peripheral circuit region, and a fourth peripheral circuit region which is disposed in the second direction with the second peripheral circuit region, is disposed in the third direction with the first peripheral circuit region, and does not overlap with the third peripheral circuit region in the second direction and the third direction. The first peripheral circuit region and the second peripheral circuit region include a row decoder circuit which is connected to the cell gate contact structure, and the third peripheral circuit region and the fourth peripheral circuit region include a page buffer circuit connected to the plurality of bit lines.

Detailed descriptions of other example embodiments are included in the detailed description and drawings.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example block diagram for describing a semiconductor memory device according to example embodiments;

FIG. 2 is an example circuit diagram for describing a semiconductor memory device according to example embodiments;

FIG. 3 is a schematic layout drawing for describing a cell structure of a semiconductor memory device according to example embodiments;

FIG. 4 is a schematic layout drawing for describing a peripheral circuit structure of a semiconductor memory device according to example embodiments;

FIG. 5 is an example drawing illustrating an enlarged view of section P of FIG. 3;

FIG. 6 is an example drawing illustrating a cross-section taken along line A-A of FIG. 3;

FIG. 7 is an example drawing illustrating an enlarged view of section A1 of FIG. 6;

FIG. 8 is another example drawing illustrating an enlarged view of section A1 of FIG. 6;

FIG. 9 is an example drawing illustrating a cross-section taken along line B-B of FIG. 3;

FIG. 10 is an example drawing illustrating an enlarged view of section A2 of FIG. 9;

FIG. 11 is an example drawing illustrating an enlarged view of section A3 of FIG. 9;

FIG. 12 is an example drawing illustrating an enlarged view of section P of FIG. 3 for describing a semiconductor memory device according to example embodiments;

FIG. 13 is an example drawing illustrating a cross-section taken along line A-A of FIG. 3 for describing a semiconductor memory device according to example embodiments;

FIG. 14 through 36 are example drawings illustrating a middle stage for describing a method of manufacturing a semiconductor memory device according to example embodiments;

FIG. 37 is an example drawing for describing an electronic system including a semiconductor memory device according to example embodiments;

FIG. 38 is an example perspective view for describing an electronic system including a semiconductor memory device according to example embodiments; and

FIG. 39 is an example drawing illustrating a cross-section taken along line I-I of FIG. 38.

### DETAILED DESCRIPTION

Before example embodiments of the present disclosure is described, terms or words used in the present disclosure and the accompanying claims are not to be limited to general definitions or dictionary definitions, and the terms and words are to be construed under the principle that an inventor may appropriately define a concept of a term in order to describe their invention in the best way. Thus, example embodiments described in the present disclosure and configurations illustrated in the accompanying drawings are merely the most desirable example embodiments and do not represent all of the technical spirit of the present disclosure, and it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that these terms are not to exclude in advance a possibility that one or more other features, numbers, operations, actions, elements, components, or combinations thereof may be present or added.

In the present disclosure, terms in a singular form include terms in a plural form unless an apparently and contextually conflicting description is present. Also, the terms “first” and “second” may be used to describe various elements throughout the specification, however, the elements should not be limited by the terms and the terms may be used for the purpose of distinguishing an element from the other elements. Within the technical spirit of the present disclosure, the first element may be referred to as a second element, and similarly, the second element may also be referred to as the first element. In addition, the shapes and sizes of the elements in the drawings may be exaggerated for emphasis and more clear description.

Also, it should be noted in advance that expressions such as an upper side, an upper surface, a lower side, a lower surface, a side surface, a front surface, or a rear surface is based on directions illustrated in the drawings and that these expressions may change when a direction of a corresponding object changes. The shapes and sizes of the elements in the drawings may be exaggerated for more clear description.

Hereinafter, example embodiments according to the technical spirit of the present disclosure will be described with reference to the drawings.

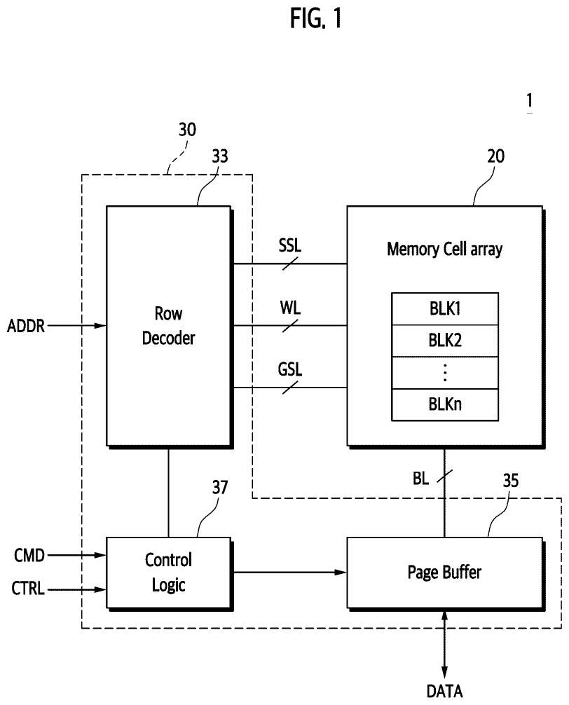

FIG. 1 is an example block diagram for describing a semiconductor memory device according to example embodiments.

Referring to FIG. 1, a semiconductor memory device 1 according to example embodiments may include a memory cell array 20 and a peripheral circuit 30.

According to example embodiments, the memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. Also, the memory cell blocks BLK1 to BLKn may be connected to a page buffer 35 through the bit line BL.

The peripheral circuit 30 may receive an address ADDR, a command CMD, and a control signal CTRL, from a source external to the semiconductor memory device 1 and may receive and transmit data DATA from and to a device external to the semiconductor memory device 1. The peripheral circuit 30 may include a control logic 37, the row decoder 33, and the page buffer 35. Although not shown in the drawings, the peripheral circuit 30 may further include various sub-circuits such as an input/output circuit, a voltage generating circuit, for generating various voltages required for operation of the semiconductor memory device 1, and an error correction circuit, for correcting errors of data DATA read out from the memory cell array 20.

The control logic 37 may be connected to the row decoder 33, the input/output circuit, and the voltage generating circuit. The control logic 37 may control overall operations of the semiconductor memory device 1. The control logic 37 may generate various internal control signals used within the semiconductor memory device 1 in response to the control signal CTRL. For example, the control logic 37, when performing a memory operation such as a program operation or an erase operation, may control a voltage level provided via word line WL and bit line BL.

The row decoder 33 may select at least one of the plurality of memory cell blocks BLK1 to BLKn in respond to the address ADDR, and may select at least one word line WL, at least one string selection line SSL, and at least one ground selection line GSL of the memory cell blocks selected among BLK1 to BLKn. Also, the row decoder 33 may forward voltage, for performing the memory operation, to the word line WL of the memory cell blocks selected among BLK1 to BLKn.

The page buffer 35 may be connected to the memory cell array 20 through the bit line BL. The page buffer 35 may operate as a writer driver or a sense amplifier. Specifically, when performing the program operation, the page buffer 35 may operate as the writer driver and apply a voltage to the bit line BL based on data DATA to be stored in the memory cell array 20. Meanwhile, when performing a read operation, the page buffer 35 may operate as the sense amplifier and detect data DATA stored in the memory cell array 20.

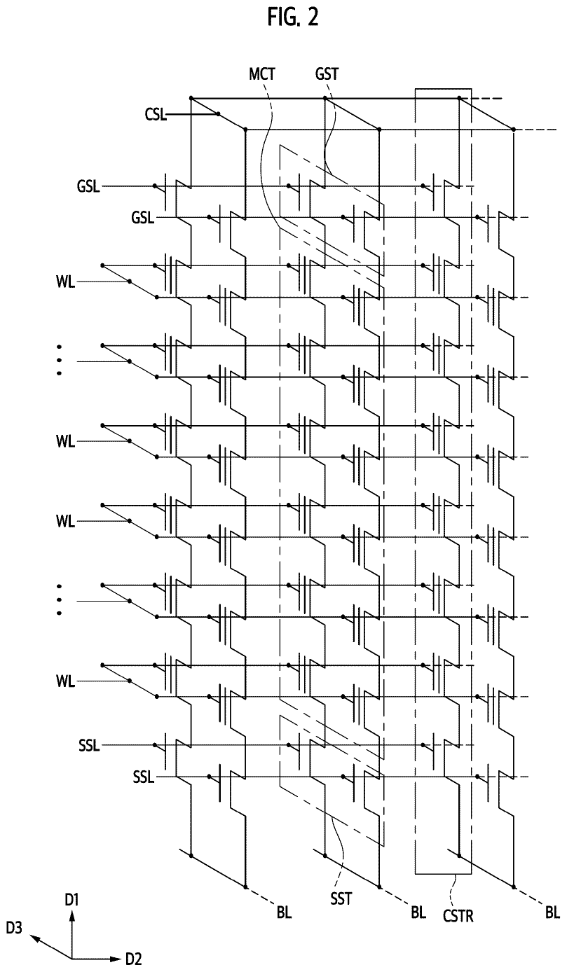

FIG. 2 is an example circuit diagram for describing a semiconductor memory device according to example embodiments.

Referring to FIG. 2, a memory cell array (e.g., 20 of FIG. 1) of the semiconductor memory device according to example embodiments may include a common source line CSL, a plurality of bit lines BL, and a plurality of cell strings CSTR.

According to example embodiments, the plurality of bit lines BL may be arranged in two-dimensional structure on a plane including a second direction D2 and a third direction D3. For example, the bit lines BL may each be extended in the third direction D3, and may be spaced apart from each other and arranged in the second direction D2. The plurality of cell strings CSTR may be connected in parallel to each bit line BL. A cell string CSTR may be commonly connected to the common source line CSL. That is, the plurality of cell strings CSTR may be disposed between the bit line BL and the common source line CSL. The plurality of cell strings CSTR may be extended in a first direction D1.

Each cell string CSTR may include a ground selection transistor GST connected to the common source line CSL, a string selection transistor SST connected to the bit line BL, and a plurality of memory cell transistors MCT disposed between the ground selection transistor GST and the string selection transistor SST. Each memory cell transistor MCT may include a data storage element. The ground selection transistor GST, the string selection transistor SST, and the memory cell transistor MCT may be connected in series.

The common source line CSL may be commonly connected to sources of the ground selection transistors GST. Also, the ground selection line GSL, a plurality of word lines WL, and the string selection line SSL may be disposed between the common source line CSL and the bit line BL. The ground selection line GSL may be used as a gate electrode of the ground selection transistor GST, the plurality of word lines WL may be used as a gate electrode of memory cell transistors MCT, and the string selection line SSL may be used as a gate electrode of the string selection transistor SST.

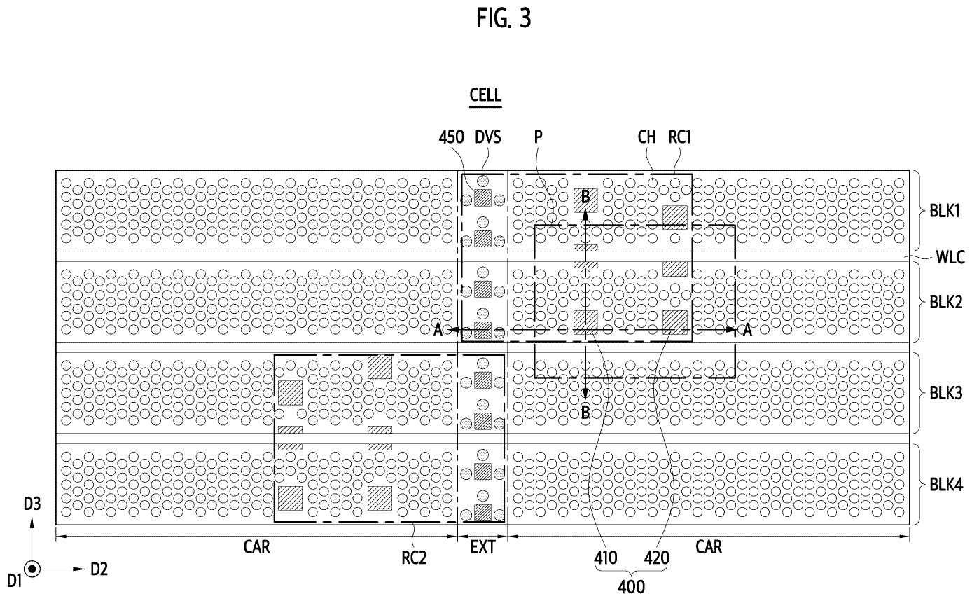

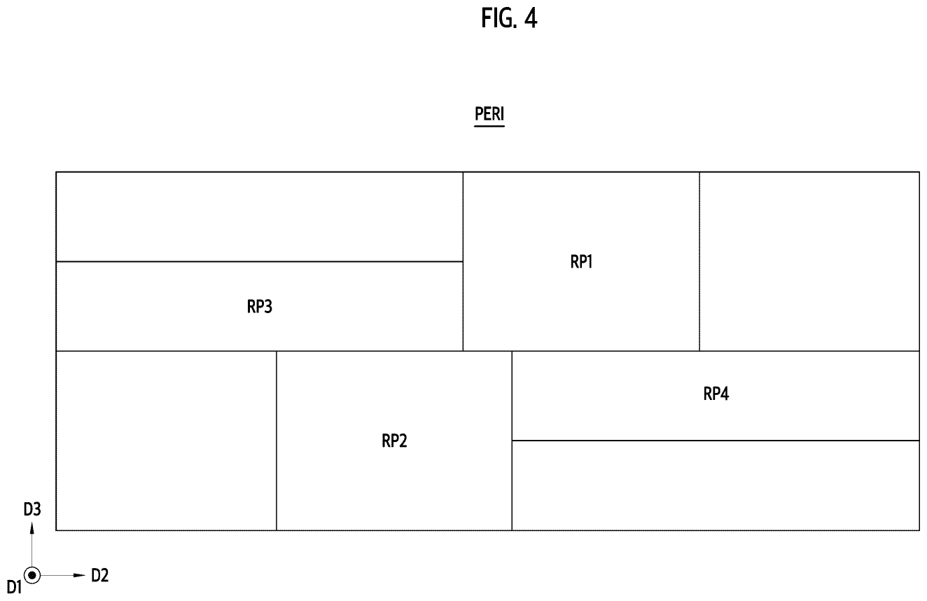

FIG. 3 is a schematic layout drawing for describing a cell structure of a semiconductor memory device according to example embodiments. FIG. 4 is a schematic layout drawing for describing a peripheral circuit of a semiconductor memory device according to example embodiments.

Referring to FIGS. 3 and 4, the semiconductor memory device according to example embodiments may include a cell structure CELL and a peripheral circuit structure PERI.

According to example embodiments, the cell structure CELL may be stacked on the peripheral circuit structure PERI. The cell structure CELL may overlap the peripheral circuit structure PERI in the first direction D1. The cell structure CELL may be bonded to the peripheral circuit structure PERI in the first direction D1.

The semiconductor memory device may include a cell array region CAR and an extension region EXT. The cell array region CAR and the extension region EXT may be disposed in the second direction D2. For example, the extension region EXT may be disposed between cell array regions CAR which are spaced apart in the second direction D2. However, this is merely an example, and example embodiments are not limited thereto. Unlike the example shown in FIG. 3, the cell array region CAR may also be disposed between the extension regions EXT which are spaced apart in the second direction D2.

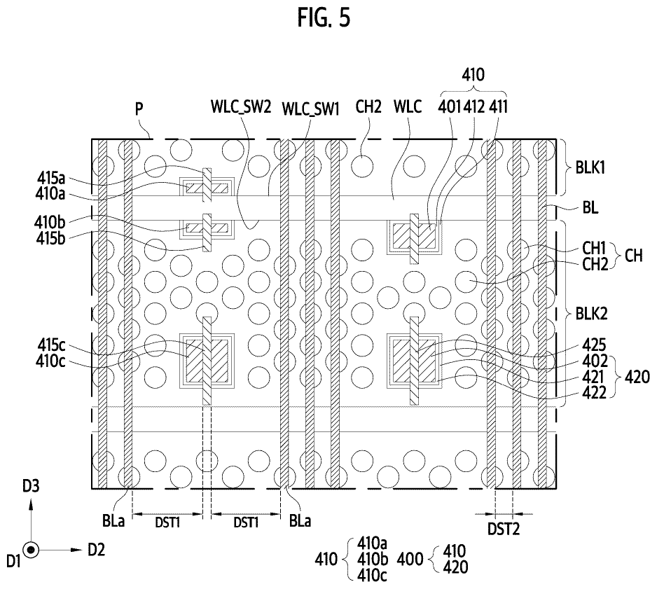

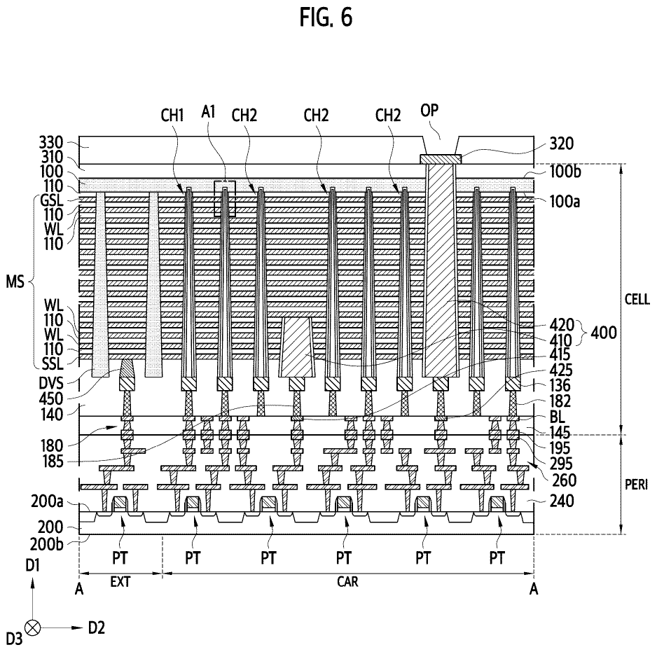

A memory cell array (e.g., 20 of FIG. 1) including a plurality of memory cells may be formed in the cell array region CAR. For example, a channel structure CH (of FIG. 5), the bit line BL (of FIG. 5), and a plurality of gate electrodes GSL, WL, and SSL (of FIG. 6), which will be described later, may be disposed in the cell array region CAR.

A cell array contact 400 may be disposed in the cell array region CAR. The cell array contact 400 may be connected to the word line WL (of FIG. 6) and the ground selection line GSL (of FIG. 6). The cell array contact 400 may pass through at least a portion of a mold structure MS (of FIG. 6).

A string selection gate contact 450 and a dummy vertical structure DVS may be disposed in the extension region EXT. The string selection gate contact 450 may be connected to the string selection line SSL (of FIG. 6). The dummy vertical structure DVS may be disposed around the string selection gate contact 450. When viewing the cell structure CELL in the first direction D1, the dummy vertical structure DVS may surround the string selection gate contact 450.

In FIG. 3, although the dummy vertical structure DVS is illustrated to be disposed in a row in the third direction D3, this is merely an example, and example embodiments are not limited thereto. As an example, the dummy vertical structure DVS may be disposed in a zigzag pattern, disposed at positions staggered from each other in the first direction D2 and the third direction D3.

In FIG. 3, although two dummy vertical structures DVS are illustrated to be disposed within each of a plurality of blocks BLK1, BLK2, BLK3, and BLK4, this is merely an example, and example embodiments are not limited thereto. The dummy vertical structure DVS may be disposed in a number equal to that of the string selection line SSL (of FIG. 6). For example, in the case of having one string selection line SSL (of FIG. 6), one dummy vertical structure DVS may be disposed within each of the plurality of blocks BLK1, BLK2, BLK3, and BLK4. As another example, in the case of having two string selection lines SSL (of FIG. 6), two dummy vertical structures DVS may be disposed within each of the plurality of blocks BLK1, BLK2, BLK3, and BLK4. However, a number of dummy vertical structures DVS to be disposed is not limited thereto, and may be changed according to example embodiments.

According to example embodiments, the cell structure CELL may include a first cell region RC1 and a second cell region RC2. The first cell region RC1 and the second cell region RC2 may not overlap in the second direction D2. A portion of the first cell region RC1 and the second region RC2 may overlap in the third direction D3. For example, the first cell region RC1 and the second cell region RC2 may overlap in the extension region EXT, in the third direction D3. The first cell region RC1 and the second cell region RC2 may be disposed at positions staggered from each other.

The first cell region RC1 and the second cell region RC2 may each include a portion of extension region EXT and a portion of the cell array region CAR adjacent in the second direction D2. Each of the first cell region RC1 and the second cell region RC2 may include a portion of the cell array region CAR, in which the cell array contact 400 is disposed. The portion of the cell array region CAR included in each of the first cell region RC1 and the second cell region RC2 may not overlap with each other in the third direction D3. The cell array region CAR in the first cell region RC1, in which the cell array contact 400 is disposed, and the cell array region CAR in the second cell region RC2, in which the cell array contact 400 is disposed, may not overlap in the third direction D3.

The peripheral circuit structure PERI may form a peripheral circuit (e.g., 30 of FIG. 1) that controls an operation of the semiconductor memory device. For example, the peripheral circuit structure PERI may include a control logic (e.g., 37 of FIG. 1), a row decoder (e.g., 33 of FIG. 1), and a page buffer (e.g., 35 of FIG. 1).

The peripheral circuit structure PERI may include a first peripheral circuit region RP1, a second peripheral circuit region RP2, a third peripheral circuit region RP3, and a fourth peripheral circuit region RP4. The first peripheral circuit region RP1 and the second peripheral circuit region RP2 may not overlap in the second direction D2. A portion of the first peripheral circuit region RP1 and the second peripheral circuit region RP2 may overlap in the third direction D3. The first peripheral circuit region RP1 and the second peripheral circuit region RP2 may be disposed at positions staggered from each other, in the second direction D2. The third peripheral circuit region RP3 and the fourth peripheral circuit region RP4 may not overlap in the second direction D2 and the third direction D3.

The first peripheral circuit region RP1 and the second peripheral circuit region RP2 of the peripheral circuit structure PERI may overlap with the first cell region RC1 and the second cell region RC2 of the cell structure CELL, respectively. A circuit forming the row decoder 33 (of FIG. 1) may be disposed in the first peripheral circuit region RP1 and the second peripheral circuit region RP2. A pass transistor which is connected to the row decoder 33 (of FIG. 1) may be disposed in the first peripheral circuit region RP1 and the second peripheral circuit region RP2. The row decoder of the first peripheral circuit region RP1 and the second peripheral circuit region RP2 may be electrically connected to the cell array contact 400 of the first cell region RC1 and the second cell region RC2 of the cell structure CELL. The pass transistor of the first peripheral circuit region PR1 and the second peripheral circuit region RP2 may be connected to the cell array contact 400 and the string selection gate contact 450 of the first cell region RC1 and the second cell region RC2 of the cell structure CELL.

The third peripheral circuit region RP3 and the fourth peripheral circuit region RP4 may each overlap with regions other than the first cell region RC1 and the second cell region RC2 of the cell structure CELL, in the first direction D1. A circuit forming the page butter 35 (of FIG. 1), for example, may be disposed in the third peripheral circuit region RP3 and the fourth peripheral circuit region PR4. A page buffer circuit of the third peripheral circuit region RP3 and the fourth peripheral circuit region RP4 may be electrically connected to the plurality of bit lines BL (of FIG. 6) of the cell structure CELL.

The first peripheral circuit region RP1 may not completely overlap with the third peripheral circuit region RP3 in the second direction D2. A portion of the first peripheral circuit region RP1 may overlap with the third peripheral circuit region RP3 in the second direction D2. The first peripheral circuit region RP1 may not completely overlap with the fourth peripheral circuit region RP4 in the third direction D3. The first peripheral circuit region RP1 may overlap with a portion of the fourth peripheral circuit region RP4 in the third direction D3.

The second peripheral circuit region RP2 may not completely overlap with the fourth peripheral circuit region RP4 in the second direction D2. A portion of the second peripheral circuit region RP2 may overlap with the fourth peripheral circuit region RP4 in the second direction D2. The second peripheral circuit region RP2 may not completely overlap with the third peripheral circuit region RP3 in the third direction D3. The second peripheral circuit region RP2 may overlap with a portion of the third peripheral circuit region RP3 in the third direction D3.

The third peripheral circuit region RP3 may be disposed in the second direction D2 with the first peripheral circuit region RP1. The third peripheral circuit region RP3 may overlap with a portion of the first peripheral circuit region RP1 in the second direction D2. The third peripheral circuit region RP3 may be disposed in the third direction D3 with the second peripheral circuit region RP2. The third peripheral circuit region RP3 may overlap with a portion of the second peripheral circuit region RP2 in the third direction D3.

The fourth peripheral circuit region RP4 may be disposed in the second direction D2 with the second peripheral circuit region RP2. The fourth peripheral circuit region RP4 may overlap with a portion of the second peripheral circuit region RP2 in the second direction D2. The fourth peripheral circuit region RP4 may be disposed in the third direction D3 with the first peripheral circuit region RP1. The fourth peripheral circuit region RP4 may overlap with a portion of the first peripheral circuit region RP1 in the third direction D3. The third peripheral circuit region RP3 and the fourth peripheral circuit region RP4 may not overlap with each other in the third direction D3.

Widths of the third peripheral circuit region RP3 and the fourth peripheral circuit region RP4 in the second direction D2 may be greater than widths of the first peripheral circuit region RP1 and the second peripheral circuit region RP2. Widths of the third peripheral circuit region RP3 and the fourth peripheral circuit region RP4 in the third direction D3 may be smaller than widths of the first peripheral circuit region RP1 and the second peripheral circuit region RP2.

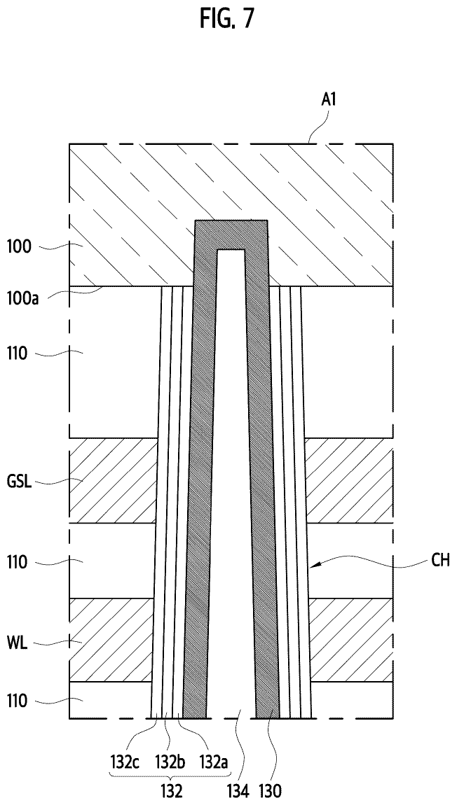

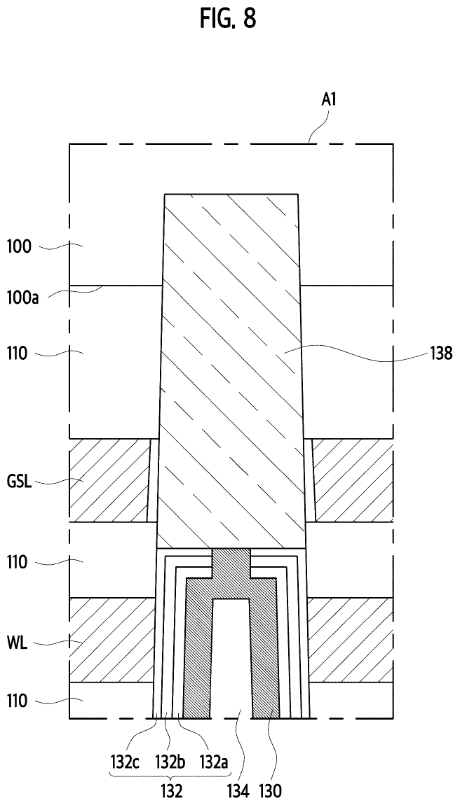

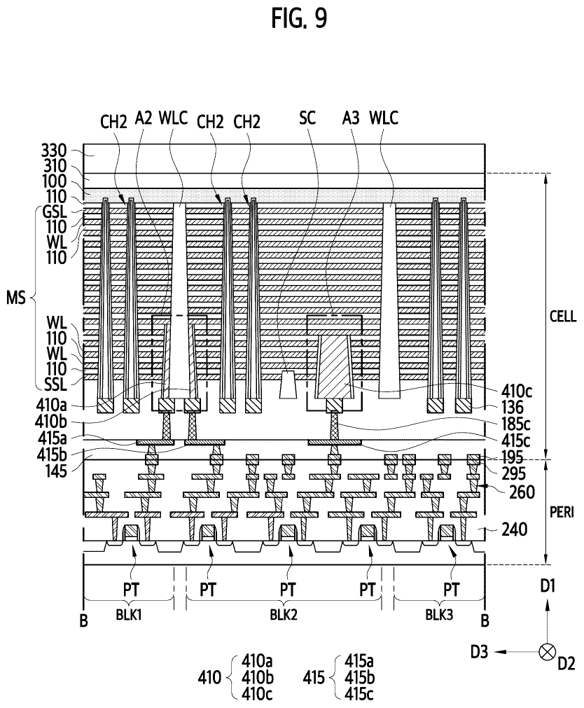

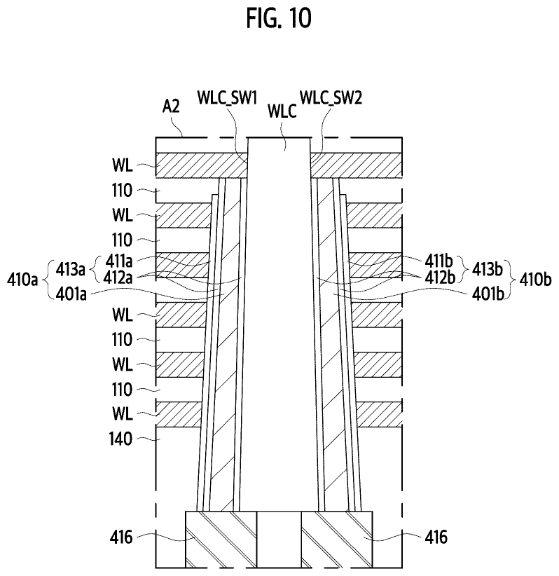

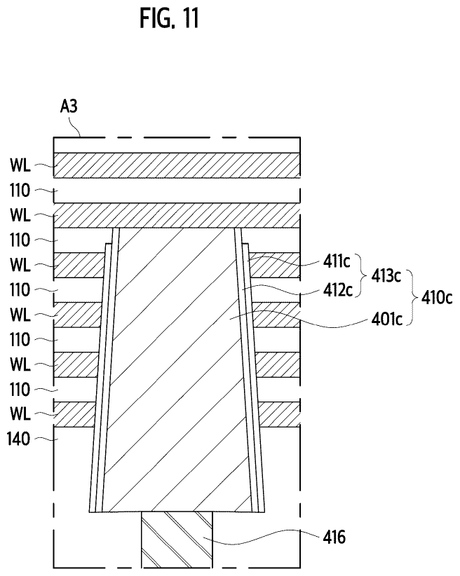

FIG. 5 is an example drawing illustrating an enlarged view of section P of FIG. 3. FIG. 6 is an example drawing illustrating a cross-section taken along line A-A of FIG. 3. FIG. 7 is an example drawing illustrating an enlarged view of section A1 of FIG. 6. FIG. 8 is another example drawing illustrating an enlarged view of section A1 of FIG. 6. FIG. 9 is an example drawing illustrating a cross-section taken along line B-B of FIG. 3. FIG. 10 is an example drawing illustrating an enlarged view of section A2 of FIG. 9. FIG. 11 is an example drawing illustrating an enlarged view of section A3 of FIG. 9.

Referring to FIGS. 3, 5, 6, and 9, the cell structure CELL may include a cell substrate 100, the mold structure MS, a first insulating interlayer 140, a gate cutting structure WLC, a channel structure CH, the bit line BL, the cell array contact 400, a contact wiring 415, a via wiring 425, and a cell wiring structure 180.

According to example embodiments, the cell substrate 100 may include a semiconductor substrate such as a silicon substrate, a germanium substrate, or a silicon-germanium substrate. Also, the cell substrate 100 may include a silicon-on-insulator (SOI) substrate, or a germanium-on-insulator (GOI) substrate.

The cell substrate 100 may include impurities. For example, the cell substrate 100 may include N-type impurities (e.g., phosphorus (P) and arsenic (As)). However, this is merely an example, and example embodiments are not limited thereto. For example, the cell substrate 100 may also include P-type impurities. The cell substrate 100 may include poly silicon (poly-Si) doped with N-type impurities. The cell substrate 100 may be provided as a common source line (e.g., CSL of FIG. 2) of the semiconductor memory device according to example embodiments.

The cell substrate 100 may include the cell array region CAR and the extension region EXT.

A memory cell array (e.g., 20 of FIG. 1) including a plurality of memory cells may be formed in the cell array region CAR. For example, the channel structure CH, the bit line BL, the plurality of gate electrodes GSL, WL, and SSL, and the like, which will be described below, may be disposed in the cell array region CAR. Hereinafter, a surface of the cell substrate 100 on which the memory cell array is disposed may be referred to as a first side 100a of the cell substrate. The first side 100a of the cell substrate may be a front side of the cell substrate 100. Alternatively, a side of the cell substrate 100 opposite to the fist side 100a of the cell substrate may be referred to as a second side 100b of the cell substrate. The second side 100b of the cell substrate may be a back side of the cell substrate 100.

The gate cutting structure WLC may pass through the mold structure MS, in the first direction D1. The gate cutting structure WLC may be extended in the second direction D2. Specifically, the gate cutting structure WLC may be extended along a plane including the first direction D1 and the second direction D2. A width of the gate cutting structure WLC in the third direction D3 may be greater than a width of the channel structure CH. The gate cutting structure WLC may be extended in the first direction D1 from the cell substrate 100 and cut the plurality of gate electrodes GSL, WL, and SSL. The gate cutting structure WLC may cut the plurality of gate electrodes GSL, WL, and SSL along the plane including the first direction D1 and the second direction D2, and separate them into a plurality of blocks. The gate cutting structure WLC may include at least one insulating material, among, for example, silicon oxide, silicon nitride, and silicon oxynitride, but this is merely an example.

The gate cutting structure WLC may be extended in the second direction D2. The gate cutting structure WLC may be extended across the cell array region CAR and the extension region EXT. For example, the gate cutting structure WLC may be extended across the cell array region CAR and the extension region EXT.

The gate cutting structure WLC may be spaced apart in the third direction D3. The gate cutting structure WLC may separate the mold structure MS into the plurality of blocks BLK1, BLK2, BLK3, and BLK 4 in the third direction D3. The plurality of blocks BLK1, BLK2, BLK3, and BLK4 may be disposed in the third direction D3. The plurality of blocks BLK1, BLK2, BLK3, and BLK4 may include a first block BLK1, a second block BLK2, a third block BLK3, and a fourth block BLK4. The gate cutting structure WLC may be disposed between the first block BLK1, the second block BLK2, the third block BLK3, and the fourth block BLK 4, which is disposed adjacent along the third direction D3.

A string selection line cutting structure SC may pass through at least a portion of the mold structure MS in the first direction D1. The string selection line cutting structure SC may cut the string selection line SSL. The string selection line cutting structure SC may be disposed between the gate cutting structures WLC in the third direction D3. A length over which the string selection line SC is extended in the first direction D1 may be smaller than a length over which the gate cutting structure WLC is extended in the first direction D1. The string selection line cutting structure SC may include an insulating material, for example, at least one of silicon oxide, silicon nitride, and silicon oxynitride, but this is merely an example.

The extension region EXT may be disposed between the cell array regions CAR. For example, the extension region EXT may be disposed at a position closer to a center portion than the cell array region CAR.

The mold structure MS may be formed on the first side 100a of the cell substrate. A thickness of the mold structure may be consistent in the first direction D1. The thickness of the mold structure MS in the first direction D1 may be consistent across the cell array region CAR and the extension region EXT. The mold structure MS may include the plurality of gate electrodes GSL, WL, and SSL and a plurality of mold insulating layers 110, which are stacked onto the cell substrate 100. The plurality of gate electrodes GSL, WL, and SSL and the plurality of mold insulating layers 110 may be alternately stacked in the first direction D1. Each of the plurality of gate electrodes GSL, WL, and SSL and each of the mold insulating layers 110 may be in a layer structure which is extended parallel to the first side 100a of the cell substrate. The plurality of gate electrodes GSL, WL, and SSL may be separated apart by a mold insulating layer 110 and sequentially stacked on the first side 100a of the cell substrate. Although it is illustrated that the plurality of gate electrodes GSL, WL, and SSL include one ground selection line GSL and one string selection line SSL, but this is merely an example, and example embodiments are not limited thereto. The plurality of gate electrodes GSL, WL, and SSL may also include two or more ground selection lines and two or more string selection lines.

The mold structure MS may be stacked on the first side 100a of the cell substrate. The mold structure MS may include the plurality of gate electrodes GSL, WL, and SSL and the mold insulating layer 110, which are alternately stacked on the cell substrate 100. The plurality of gate electrodes GSL, WL, and SSL may include the ground selection line GSL, the word line WL, and the string selection line SSL, which are sequentially stacked on the cell substrate 100.

Each of the plurality of gate electrodes GSL, WL, and SSL may include a conductive material, for example, a metal such as tungsten (W), cobalt (Co), and nickel (Ni), and a semiconductor material such as silicon, but this is merely an example.

The mold insulating layers 110 may each include an insulating material. For example, the mold insulating layer 110 may include at least one of silicon oxide, silicon nitride, and silicon oxynitride, but this is merely an example.

The first insulating interlayer 140 may be formed on the first side 100a of the cell substrate and cover the mold structure MS. The first insulating interlayer 140, for example, may include at least one of silicon oxide, silicon nitride, and a low-k material having lower dielectric constant than silicon oxide, but this is merely an example.

The channel structure CH may be formed within the mold structure MS of the cell array region CAR. The channel structure CH may be extended in the first direction D1, vertical to the first side 100a of the cell substrate, and pass through the mold structure MS. For example, the channel structure CH may have a pillar shape (e.g., a cylindrical shape) extended in the first direction D1. Accordingly, the channel structure CH may cross with each of the plurality of gate electrodes GSL, WL, and SSL.

The channel structure CH may be arranged in a zigzag pattern. For example, the channel structures CH may be arranged at positions staggered from each other in the second direction D2 and the third direction D3 parallel to an upper surface of the cell substrate 100. A plurality of channel structures CH arranged in a zigzag pattern may improve integration of the semiconductor memory device. The plurality of channel structures CH may be arranged in a honeycomb pattern.

Referring to FIGS. 6 and 7, the channel structure CH may include a semiconductor pattern 130 and a data storage layer 132.

According to example embodiments, the semiconductor pattern 130 may be extended in the first direction D1 and cross the plurality of gate electrodes GSL, WL, and SSL. Although only a case in which the semiconductor pattern 130 has a shape of a cup is illustrated, this is merely an example. For example, the semiconductor pattern 130 may have a different shape such as a cylindrical shape, a square pillar shape, and a filled pillar shape. The semiconductor pattern 130 may include a semiconductor material such as single crystal silicon, polycrystalline silicon, organic semiconductor substance, and carbon nanostructure, but this is merely an example.

The semiconductor pattern 130 may be connected to the cell substrate 100. For example, one end (e.g., upper part) of the semiconductor pattern 130 may be exposed from the data storage layer 132 and connected to the cell substrate 100. According to example embodiments, the semiconductor pattern 130 may pass through the first side 100a of the cell substrate 100. For example, one end (e.g., upper part) of the semiconductor pattern 130 may be further protruded than the data storage layer 132. The semiconductor pattern 130 may improve contact resistance by increasing contact area with the cell substrate 100.

The data storage layer 132 may be interposed between the semiconductor pattern 130 and each of the gate electrodes GSL, WL, and SSL. For example, the data storage layer 132 may be extended along an outer surface of the semiconductor pattern 130. The data storage layer 132, for example, may include at least one of silicon oxide, silicon nitride, silicon oxynitride, and a high dielectric constant material having a higher dielectric constant than silicon oxide. The high dielectric constant material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

The data storage layer 132 may be formed as multiple layers. For example, as shown in FIG. 7, the data storage layer 132 may include a tunnel insulating layer 132a, a charge storage layer 132b, and blocking insulating layer 132c, which are sequentially stacked on the outer surface of the semiconductor pattern 130.

The tunnel insulating layer 132a, for example, may include silicon oxide or a high dielectric constant material with higher dielectric constant than silicon oxide (e.g., aluminum oxide (Al₂O₃), hafnium oxide (HfO₂)). The charge storage layer 132b, for example, may include silicon nitride. The blocking insulating layer 132c, for example, may include silicon oxide or a high dielectric constant material with higher dielectric constant than silicon oxide (e.g., aluminum oxide (Al₂O₃), hafnium oxide (HfO₂)).

The channel structure CH may further include a filling insulating layer 134. The filling insulating layer 134 may be formed to fill the semiconductor pattern 130 which has a shape of a cup. The filling insulating layer 134 may include an insulating material, such as silicon oxide, but this is merely an example.

Referring to FIGS. 6 through 8, the channel structure CH may further include a source pattern 138. The source pattern 138 may be formed on the cell substrate 100. The source pattern 138 may be connected to the semiconductor pattern 130. For example, the semiconductor pattern 130 may pass through the data storage layer 132 and be in contact with the source pattern 138. The source pattern 138 may include a conductive material, for example, such as poly silicon doped with impurities, or metal, but this is merely an example. The source pattern 138 and the cell substrate 100 may be provided as a common source line (e.g., CSL of FIG. 2) of the semiconductor memory device.

According to example embodiments, the source pattern 138 may be an epitaxial pattern which is formed through a selective epitaxial growth process from the cell substrate 100.

Referring to FIGS. 3, 5, 6, and 9 again, the channel structure CH may further include a channel pad 136. The channel pad 136 may be formed to be connected to the other end (e.g., lower part) of the semiconductor pattern 130. The channel pad 136 may include a conductive material, for example, such as poly silicon doped with impurities or metal, but this is merely an example.

According to example embodiments, the channel structure CH may include a first channel structure CH1 and a second channel structure CH2. The first channel structure CH1 may be connected to the bit line BL. The first channel structure CH1 may overlap with the bit line BL in the first direction D1. The first channel structure CH1 may be electrically connected to the bit line Bl through a bit line contact 182.

The second channel structure CH2 may not be connected to the bit line BL. The second channel structure CH2 may not overlap with the bit line BL in the first direction D1. The bit line contact 182 connected to the second channel structure CH2 may not be in contact with the bit line BL. The second channel structure CH2 may surround the cell array contact 400. The second channel structure CH2 may be disposed closer to the cell array contact 400 than the first channel structure CH1. The second channel structure CH2 may overlap with the cell array contact 400 in the third direction D3. The second channel structure CH2 may overlap with a cell gate contact structure 410 in the third direction D3.

The bit line BL may be disposed below the mold structure MS. The bit line BL may be formed on the first side 100a of the cell substrate 100. The bit line BL may be extended in the third direction D3 and cross the gate cutting structure WLC. Also, the bit line BL may be extended in the third direction D3 and connected to a plurality of channel structures CH which are arranged in the third direction D3. For example, the bit line contact 182 connected to upper surfaces of each channel structures CH may be formed within the first insulating interlayer 140. The bit line BL may be electrically connected to the channel structure CH through the bit line contact 182.

The bit line BL may include a nearest neighboring bit line BLa which is most adjacent to the cell array contact 400 in the second direction D2 among the plurality of bit lines BL. For example, the nearest neighboring bit line BLa may be disposed most adjacent to the cell gate contact structure 410 in the second direction D2 among the plurality of bit lines BL. A first distance DST1 between the nearest neighboring bit line BLa and a contact wiring 415 in the second direction D2 may be greater than a second distance DST2 between the plurality of bit lines BL. The first distance DST1 may be more than twice the second distance DST2. The plurality of bit lines BL may be disposed on one side of the cell gate contact structure 410. The plurality of bit lines BL may include a first bit line and a second bit line which are more adjacent to the contact wiring 415 in the second direction D2 than other bit lines among the plurality of bit lines BL. The first bit line may be disposed between the contact wiring 415 and the second bit line. The first bit line may be the nearest neighboring bit line BLa. The first distance DST1 may be a distance between the contact wiring 415 and the first bit line in the second direction D2. The second distance DST2 may be a distance between the first bit line and the second bit line in the second direction D2.

The bit line BL may be disposed in the first cell region RC1 and the second cell region RC2, in which the plurality of channel structures CH and the cell gate contact structure 410 are disposed. A plurality of the cell gate contact structures 410 may be disposed in the first cell region RC1. The cell gate contact structure 410 may include a plurality of contact structures which are spaced apart and disposed in the second direction D2. At least one bit line BL among the plurality of bit lines BL may be disposed between a plurality of cell gate contact structures 410, which are spaced apart and disposed in the second direction D2.

The cell array contact 400 may be disposed in the cell array region CAR. The cell array contact 400 may be surrounded by the plurality of channel structures CH. The cell array contact 400 may be disposed between the plurality of channel structures CH. The cell array contact 400 may overlap with the plurality of channel structures CH in the second direction D2 and the third direction D3. The cell array contact 400 may be connected to at least one of the plurality of gate electrodes GSL, WL, and SSL. The cell array contact 400 may be connected to the ground selection line GSL and the word line WL. The cell array contact 400 may apply voltage to the plurality of gate electrodes GSL, WL, and SSL. The cell array contact 400 may electrically connect the plurality of gate electrodes GSL, WL, and SSL, to the cell wiring structure 180.

The cell array contact 400 may include the cell gate contact structure 410 and a through via structure 420. The cell gate contact structure 410 and the through via structure 420 may pass through at least a portion of the mold structure MS. The cell gate contact structure 410 and the through via structure 420 may be surrounded by the plurality of channel structures CH. The cell gate contact structure 410 and the through via structure 420 may be disposed between the plurality of channel structures CH. The cell gate contact structure 410 and the through via structure 420 may be disposed between the second channel structures CH2.

The cell gate contact structure 410 may pass through at least a portion of the mold structure MS in the first direction D1. The cell gate contact structure 410 may be connected to one of the plurality of gate electrodes GSL, WL, and SSL. The cell gate contact structure 410 may be connected to the ground selection line GSL and the word line WL among the plurality of gate electrodes GSL, WL, and SSL. For example, one cell gate contact structure 410 may be connected to one ground selection line GSL. Another cell gate contact structure 410 may be connected to one word line WL.

The cell gate contact structure 410 may electrically connect the ground selection line GSL and the word line WL to the cell wiring structure 180. The cell gate contact structure 410 may transmit a voltage signal, forwarded to the cell wiring structure 180 from the cell peripheral circuit structure PERI, to the ground selection line GSL and the word line WL.

Referring to FIGS. 3, 5, 9, 10, and 11, the cell gate contact structure 410 may be disposed in a plurality of memory cell blocks BLK1 to BLK4. The cell gate contact structure 410 may be disposed in each of the first block BLK1, the second block BLK2, the third block BLK3, and the fourth block BLK4, in plural numbers. The cell gate contact structure 410 may include a first contact structure 410a, a second contact structure 410b, and a third contact structure 410c.

According to example embodiments, the first contact structure 410a and the second contact structure 410b may be spaced apart in the third direction D3 with the gate cutting structure WLC in between. The first contact structure 410a and the second contact structure 410b may be extended along side walls WLC_SW1 and WLC-SW2 of the gate cutting structure WLC. The first contact structure 410a may be extended along a first side wall WLC-SW1 of the gate cutting structure WLC. The second contact structure 410b may be extended along a second side wall WLC-SW2 of the gate cutting structure WLC.

The first contact structure 410a and the second contact structure 410b may be connected to gate electrodes of the first block BLK1 and the second block BLK2, respectively. The first contact structure 410a may be connected to the word line WL of the first block BLK1 and the second contact structure 410b may be connected to the word line WL of the second block BLK2.

A gate electrode to which the first contact structure 410a and the second contact structure 410b are each connected may be the same gate electrode. For example, the gate electrode (WL, for example) to which the first contact structure 410a is connected and the gate electrode (WL, for example) to which the second contact structure 410b is connected may be the same. The gate electrode (WL, for example) to which the first contact structure 410a is connected and the gate electrode (WL, for example) to which the second contact structure 410b is connected may have an equal vertical level in the first direction D1.

A width of the first contact structure 410a and a width of the second contact structure 410b in the third direction D3 may be smaller than a width of the third contact structure 410c.

The third contact structure 410c may be spaced apart from the gate cutting structure WLC in the third direction D3. The third contact structure 410c may be disposed in the memory cell blocks BLK1 to BLK4 in which one of the first contact structure 410a and the second contact structure 410b is disposed. For example, the third contact structure 410c may be disposed in the same memory cell block as the second contact structure 410b. The third contact structure 410c and the second contact structure 410b may be disposed in the second block BLK2.

The gate electrode to which the third contact structure 410c is connected may be different from the gate electrode to which the first contact structure 410a and the second contact structure 410b are connected. For example, the gate electrode (WL, for example) to which the third contact structure 410c is connected may be different from the gate electrode (WL, for example) to which the first contact structure 410a is connected and the gate electrode (WL, for example) to which the second contact structure 410b is connected. A vertical level of the gate electrode (WL, for example) to which the third contact structure 410c is connected to in the first direction D1 may be different from vertical levels of gate electrodes (WL, for example) to which the first contact structure 410a and the second contact structure 410b are connected.

The second contact structure 410b and the third contact structure 410c disposed in the same second block BLK2 may be electrically connected to different gate electrodes. Accordingly, a plurality of gate electrodes disposed in the same memory cell block may be electrically connected to the cell wiring structure 180 through the second contact structure 410b and the third contact structure 410c each.

A width of the third contact structure 410c in the third direction D3 may be greater than a width of the second contact structure 410b of the first contact structure 410a.

The cell gate contact structure 410 may include a contact conductive layer 401, an external insulating layer 411, and internal insulating layer 412. The contact conductive layer 401 may be in contact with one of the plurality of gate electrodes GSL and WL. The internal insulating layer 412 may surround the contact conductive layer 401. The internal insulating layer 412 may be disposed between the contact conductive layer 401 and the external insulating layer 411. The external insulating layer 411 may surround the internal insulating layer 412. The external insulating layer 411 may be disposed between the internal insulating layer 412 and the mold structure MS.

The contact conductive layer 401 may include a conductive material, for example, a metal such as tungsten (W), cobalt (Co), and nickel (Ni), or a semiconductor material such as silicon, but this is merely an example. The external insulating layer 411 and the internal insulating layer 412 each may include a conductive material. For example, the external insulating material 411 and the internal insulating material 412 may include at least one of silicon oxide, silicon nitride, and silicon oxynitride, but this is merely an example.

The first contact structure 410a may include a first contact conductive layer 401a, a first external insulating layer 411a, and a first internal insulating layer 412a. The second contact structure 410b may include a second contact conductive layer 401b, a second external insulating layer 411b, and a second internal insulating layer 412b. The third contact structure 410c may include a third contact conductive layer 401c, a third external insulating layer 411c, and a third internal insulating layer 412c.

The first external insulating layer 411a and the second external insulating layer 411b of the first contact structure 410a and the second contact structure 410b respectively, which are extended along the side walls WLC_SW1 and WLC_SW2 of the gate cutting structure WLC, may not be extended along the side walls WLC_SW1 and WLC-SW2 of the gate cutting structure WLC. The first external insulating layer 411a may not be disposed between the first internal insulating layer 412a and a first side wall WLC-SW1 of the gate cutting structure WLC. The first external insulating layer 411a may be disposed between the first internal insulating layer 412a and the mold structure MS. The second external insulating layer 411b may not be disposed between the second internal insulating layer 412b and a second side wall WLC-SW2 of the gate cutting structure WLC. The second external insulating layer 411b may be disposed between the second internal insulating layer 412b and the mold structure MS.

A contact pad 416 may be disposed on the cell gate contact structure 410. The contact pad 416 may be in contact with the contact conductive layer 401 of the cell gate contact structure 410. The contact pad 416 may include a conductive material, for example, such as poly silicon doped with impurities, or a metal, but this is merely an example.

The cell gate contact structure 410 may be connected to the contact wiring 415 through the contact pad 416. The cell gate contact structure 410 may be connected to the contact wiring 415 through a contact connection plug 185. The contact wiring 415 may be disposed at the same vertical level as the bit line BL, in the first direction D1. The contact wiring 415 may be spaced apart from the bit line BL in the second direction D2. The first distance DST1 between the contact wiring 415 and the nearest neighboring bit line BLa may be greater than the second distance DST2 between the two bit lines BL which are adjacent to each other in the second direction D2.

A length over which the contact wiring 415 is extended in the third direction D3 may be smaller than a length over which the bit line BL is extended. The contact wiring 415 may include a first contact wiring 415a connected to the first contact structure 410a, a second contact wiring 415b connected to the second contact structure 410b, and a third contact wiring 415c connected to the third contact structure 410c. The first contact wiring 415a, the second contact wiring 415b, and the third contact wiring 415c may be spaced apart in the third direction D3.

The through via structure 420 may pass through the mold structure MS in the first direction D1. The through via structure 420 may connect an input/output pad 320 and the cell wiring structure 180. The input/output pad 320 may be electrically connected to the cell structure CELL and/or the peripheral circuit structure PERI. The input/output pad 320 may be connected to the cell wiring structure 180 via through via structure 420. The through via structure 420 may be disposed in the cell array region CAR with the channel structure CH. A length over which the through via structure 420 is extended in the first direction D1 may be greater than a length over which the cell gate contact structure 410 is extended in the first direction D1.

A description of the through via structure 420 will be omitted as is substantially the same as a description of the cell gate contact structure 410.

The through via structure 420 may be connected to the via wiring 425. A distance between the bit line BL which is most adjacent to the via wiring 425 in the second direction D2, which is connected to the through via structure 420, and the via wiring 425 may be greater than a distance between the two bit lines BL adjacent to each other in the second direction D2.

A description of the via wiring 425 will be omitted as is substantially the same as a description of the contact wiring 415.

A thickness in the first direction D1 of the mold structure MS in which the cell array contact 400 passed through in the first direction D1 in the cell array region CAR, and a thickness in the first direction D1 of the mold structure in which the channel structure CH passes through in the first direction D1 may be equal. A thickness in the first direction D1 of a region of the mold structure MS in which the cell array contact 400 is disposed, and a thickness in the first direction D1 of a region of the mold structure MS in which the channel structure CH is disposed may be equal. A thickness in the first direction D1 of a region of the mold structure MS in which the cell gate contact structure 410 is disposed, and a thickness in the first direction D1 of a region of the mold structure MS in which the channel structure CH is disposed, may be equal. That is, the mold structure MS may have a consistent thickness in the first direction D1 across the entire region in which the cell array contact 400 and the channel structure CH are disposed.

The string selection gate contact 450 may be disposed in the extension region EXT. The string selection gate contact 450 may be disposed between the dummy vertical structure DVS. The string selection gate contact 450 may be surrounded by the dummy vertical structure DVS. The string selection gate contact 450 may be electrically connected to the string selection line SSL among the plurality of gate electrodes GSL, WL, and SSL. The dummy vertical structure DVS may include, for example, an insulating material. The dummy vertical structure DVS may include at least one of silicon oxide, silicon nitride, and silicon oxynitride, but this is merely an example.

The cell wiring structure 180 may be formed above the mold structure MS. The cell wiring structure 180 may be disposed above the first side 100a of the cell substrate. For example, a first inter-wire insulating layer 145 may be formed on the first insulating interlayer 140, and the cell wiring structure 180 may be formed within the first inter-wire insulating layer 145. The cell wiring structure 180 may be electrically connected to the bit line BL, the string selection gate contact 450, and the cell array contact 400. Through this, the cell wiring structure 180 may be electrically connected to the channel structure CH, the plurality of gate electrodes GSL, WL, and SSL, and cell substrate 100. A number and arrangement of layers illustrated in the drawings are merely an example, and are not limited thereto.

The cell wiring structure 180 may be electrically connected to the plurality of memory cells formed in the cell array region CAR. For example, the cell wiring structure 180 may be electrically connected to the bit line BL. Through this, the cell wiring structure 180 may be electrically connected to the channel structure CH.

The peripheral circuit structure PERI may include a peripheral circuit substrate 200, a peripheral circuit element PT, and a peripheral circuit wiring structure 260.

The peripheral circuit substrate 200 may be disposed below the cell substrate 100. For example, the peripheral circuit substrate 200 may face the first side 100a of the cell substrate. The peripheral circuit substrate 200, for example, may include a semiconductor substrate such as a silicon substrate, a germanium substrate, or a silicon-germanium substrate. Or, the peripheral circuit substrate 200 may include a silicon-on-insulator (SOI) substrate or a germanium-on-insulator (GOI) substrate.

The peripheral circuit element PT may be formed on the peripheral circuit substrate 200. The peripheral circuit element PT may form a peripheral circuit (e.g., 30 of FIG. 1) for controlling an operation of the semiconductor memory device. For example, the peripheral circuit element PT may include a control logic (e.g., 37 of FIG. 1), a row decoder (e.g., 33 of FIG. 1), and a page buffer (e.g., 35 of FIG. 1). In below description, a surface of the peripheral circuit substrate 200 on which the peripheral circuit element PT is disposed may be referred to as a first side 200a of the peripheral circuit substrate 200. The first side 200a of the peripheral circuit substrate may be a front side of the peripheral circuit substrate 200. Alternatively, a surface of the peripheral circuit substrate 200 opposite to the first side 200a of the peripheral circuit substrate may be referred to as a second side 200b of the peripheral circuit substrate. The second side 200b of the peripheral circuit substrate may be a back side of the peripheral circuit substrate.

The peripheral circuit element PT, for example, may include a transistor, but this is merely an example. For example, the peripheral circuit element PT may include an active element as well as a passive element such as a capacitor, a resistor, and an inductor.

The cell structure CELL may be stacked on the peripheral circuit structure PERI. For example, the cell structure CELL may be stacked on the first side 200a of the peripheral circuit substrate. The first side 100a of the cell substrate 100 may face the peripheral circuit structure PERI. For example, the first side 100a of the cell substrate 100 may face the first side 200a of the peripheral circuit substrate.

The semiconductor memory device may have a chip-to-chip (C2C) structure. The C2C structure refers to a method of fabricating an upper chip including the cell structure CELL on a first wafer (e.g., the cell substrate 100), fabricating a lower chip including the peripheral circuit structure PERI on a second wafer (e.g., the peripheral circuit substrate 200) which is different from the first wafer, and connecting the upper chip and the lower chip through bonding.

As an example, the bonding method above may refer to a method of electrically connecting a first bonding metal 195 formed on an uppermost metal layer of the upper chip and a second bonding metal 295 formed on an uppermost metal layer of the lower chip. That is, when the first bonding metal 195 and the second bonding metal 295 are made of copper (Cu), the bonding may be a Cu-Cu bonding scheme. However, this is merely an example, and the first bonding metal 195 and the second bonding metal 295 may also be made of different metals such as aluminum (Al) or tungsten (W).

As the first bonding metal 195 and the second bonding metal 295 are bonded to each other, the cell wiring structure 180 may be connected to the peripheral circuit wiring structure 260. Through this, the bit line BL, each of the gate electrodes GSL, WL, and SSL, and/or the cell substrate 100 may be electrically connected to the peripheral circuit element PT.

The input/output pad 320 may be disposed above the second side 100b of the cell substrate 100. For example, a second insulating interlayer 310 which covers the cell substrate 100 may be disposed on the second side 100b of the cell substrate 100. The input/output pad 320 may be formed on the second insulating interlayer 310. The second insulating interlayer 310, for example, may include at least one of silicon oxide, silicon nitride, and a low-k material having smaller dielectric constant than silicon oxide, but this is merely an example.

A capping insulating layer 330 may be disposed on the input/output pad 320. The capping insulating layer 330 may include a pad opening OP which exposes at least a portion of the input/output pad 320. The input/output pad 320 may be electrically connected to, for example, an external device through the pad opening OP.

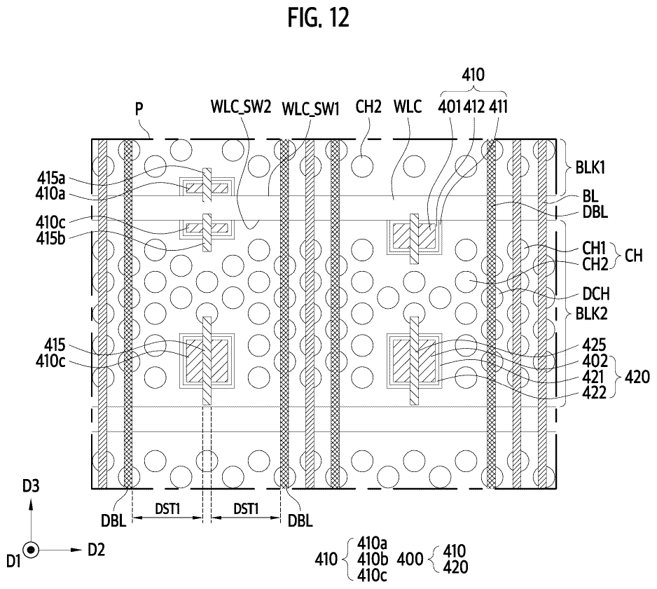

FIG. 12 is an example drawing illustrating an enlarged view of section P of FIG. 3 for describing a semiconductor memory device according to example embodiments. A description other than the descriptions provided with reference to FIGS. 3 through 11 will be provided to describe the semiconductor memory device according to other example embodiments.

Referring to FIG. 12, the plurality of bit lines BL may include a dummy bit line DBL. The dummy bit line DBL, among the plurality of bit lines BL, may be disposed closest to the cell array contact 400 in the second direction D2. The dummy bit line DBL may correspond to the nearest neighboring bit line BLa described with referent to FIG. 5. A level of a signal applied to the dummy bit line DBL may be different from levels of signals applied to the plurality of bit lines BL other than the dummy bit line DBL. For example, the dummy bit line DBL may be electrically floated or provided with a grounding voltage. The dummy bit line DBL may not be connected to the first channel structure CH1. The dummy bit line DBL may not be connected to the channel structure CH which is used as a memory cell. The dummy bit line DBL may be connected to a dummy channel structure DCH. The dummy channel structure DCH may not be used as a memory cell. The dummy bit line DBL may reduce electrical resistance occurring between wirings 415 and 425, connected to the cell array contact 400, and the plurality of bit lines BL.

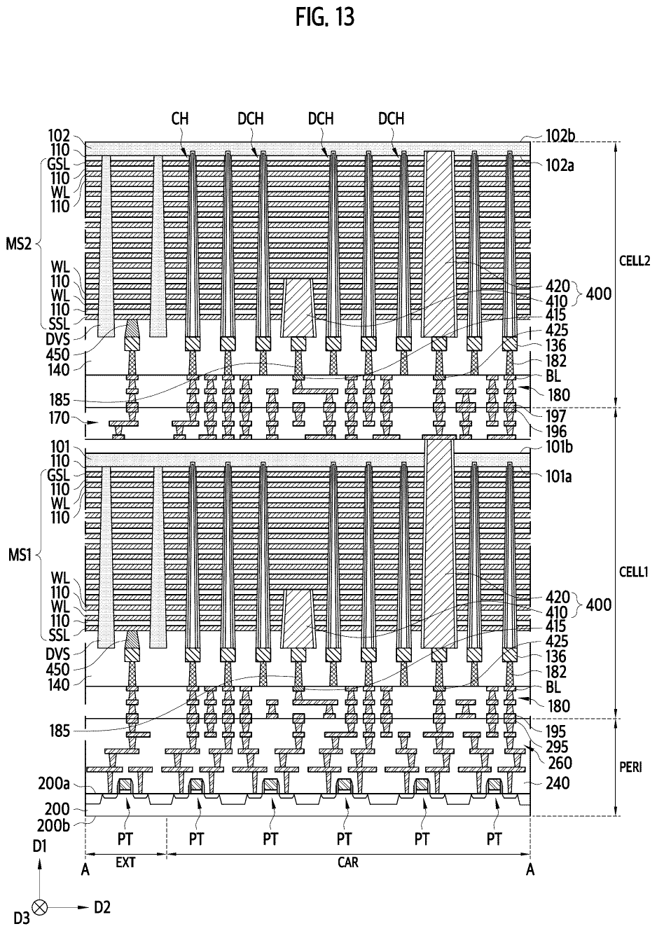

FIG. 13 is an example drawing illustrating a cross-section taken along line A-A of FIG. 3 for describing a semiconductor memory device according to other example embodiments. A description other than the description provided with reference to FIG. 6 will be provided mainly to describe the semiconductor memory device according to other example embodiments.

Referring to FIG. 13, the semiconductor memory device according to other example embodiments may include cell structures CELL1 and CELL2 and the peripheral circuit structure PERI.

According to example embodiments, the cell structures CELL1 and CELL2 may be stacked onto the peripheral circuit structure PERI. The cell structure CELL may include a first cell structure CELL1 and a second cell structure CELL2. The fist cell structure CELL1 and the second cell structure CELL2 may be sequentially stacked onto the peripheral circuit structure PERI. The first cell structure CELL1 and the second cell structure CELL2 may be bonded to each other in the first direction D1.

The first cell structure CELL1 may include a first cell substrate 101, a first mold structure MS1, cell wiring structures 170 and 180, and the cell array contact 400. The first cell structure CELL1 may be disposed between the peripheral circuit structure PERI and the second cell structure CELL2 in the first direction D1. The first cell structure CELL1 may be bonded to the peripheral circuit structure PERI and the second cell structure CELL2.

A first side 101a of the first cell substrate 101 may face the peripheral circuit structure PERI. For example, the first side 101a of the first cell substrate 101 may face the first side 200a of the peripheral circuit substrate. A second side 101b of the fist cell substrate 101 may face the second cell structure CELL2. The second side 101b of the first cell substrate 101 may face a first side 102a of the second cell substrate 102.

The cell wiring structures 170 and 180 of the first cell structure CELL1 may include a first cell wiring structure 180 and a second cell wiring structure 170. The first cell wiring structure 180 of the first cell structure CELL1 may face the peripheral circuit wiring structure 260. The second cell wiring structure 170 of the first cell structure CELL1 may face the first cell wiring structure 180 of the second cell structure CELL2.

The cell array contact 400 of the first cell structure CELL1 may include the cell gate contact structure 410 and the through via structure 420. The cell gate contact structure 410 and the through via structure 420 of the first cell structure CELL1 may each be electrically connected to the through via structure 420 of the second cell structure CELL2 via cell wiring structures 170 and 180 of the first cell structure CELL1. The cell gate contact structure 410 and the through via structure 420 of the first cell structure CELL1 may each be electrically connected to the peripheral circuit structure PERI through the first cell wiring structure 180 of the first cell structure CELL1. The cell wiring structures 170 and 180 of the first cell structure CELL1 may be electrically connected to the through via structure 420 of the second cell structure CELL2.

The second cell structure CELL2 may include the second cell substrate 102, a second mold structure MS2, and the cell array contact 400. The second cell structure CELL2 may be disposed above the peripheral circuit structure PERI and the first cell structure CELL1, in the first direction D1. The second cell structure CELL2 may be bonded to the first cell structure CELL1.

The first cell wiring structure 180 of the second cell structure CELL2 and the second cell wiring structure 170 of the first cell structure CELL1 may be electrically connected. A third bonding metal 196 of the first cell structure CELL1 and a fourth bonding metal 197 of the second cell structure CELL2 may be bonded. The third bonding metal 196 of the first cell structure CELL1 may be connected to the second cell wiring structure 170 of the first cell structure CELL1. The fourth bonding metal 197 of the second cell structure CELL2 may be connected to the first cell wiring structure 180 of the second cell structure CELL2.

The first side 102a of the second cell substrate 102 may face the first cell structure CELL1. For example, the first side 102a of the second cell substrate 102 may face the first cell substrate CELL1. The first side 102a of the second cell substrate 102 may face the second side 101b of the first cell substrate 101.

The cell array contact 400 of the second cell structure CELL2 may include the cell gate contact structure 410 and the through via structure 420. The cell gate contact structure 410 and the through via structure 420 of the second cell structure CELL2 may each be electrically connected to the cell wiring structure 170 and the through via structure 420 of the first cell structure CELL1 through the first cell wiring structure 180 of the second cell structure CELL2. The cell gate contact structure 410 and the through via structure 420 of the second cell structure CELL2 may be electrically connected to the peripheral circuit structure PERI through the first cell wiring structure 180 of the second cell structure CELL2, the cell wiring structures 170 and 180 of the first cell structure CELL1, and the through via structure 420. The first cell wiring structure 180 of the second cell structure CELL2 may be electrically connected to the peripheral circuit structure PERI.

Descriptions of the fist cell structure CELL1 and the second cell structure CELL2 of FIG. 13 will be omitted as are substantially identical to the descriptions of the cell structure CELL described with reference to FIGS. 3, 5, 6, and 9. A description of the peripheral circuit structure PERI of FIG. 13 will be omitted as is substantially identical to the descriptions of the peripheral circuit structure PERI described with reference to FIGS. 3, 5, 6, and 9. The cell wiring structures 170 and 180 of the first cell structure CELL1 and the first cell wiring structure 180 of the second cell structure CELL2 in FIG. 13 may be substantially identical to the description of the cell wiring structure 180 described with reference to FIG. 6.

According to example embodiments, a first chip including the first cell structure CELL1 may be fabricated on the first wafer (e.g., the first cell substrate 101). A second chip including the second cell structure CELL2 may be fabricated on the second wafer (e.g., the second cell substrate 102). A third chip including the peripheral circuit structure PERI may be fabricated on a third wafer (e.g., the peripheral circuit substrate 200) other than the first wafer and the second wafer. Once the first chip, the second chip, and the third chip each are fabricated, the first chip, the second chip, and the third chip may be connected to each other through bonding.

Although two cell structures (e.g., the fist cell structure CELL1 and the second cell structure CELL2) are illustrated to be disposed on the peripheral circuit structure PERI in FIG. 13, this is merely an example, and example embodiments are not limited thereto. For example, there may also be three or more cell structures disposed on the peripheral circuit structure PERI.

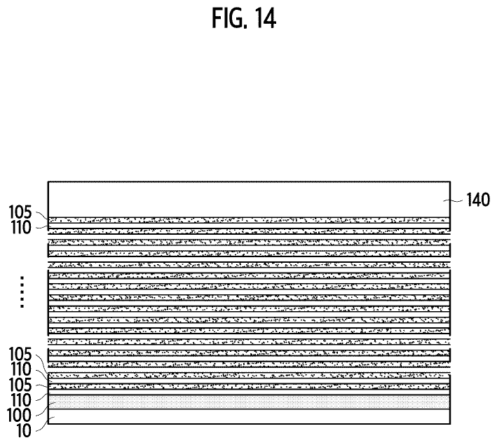

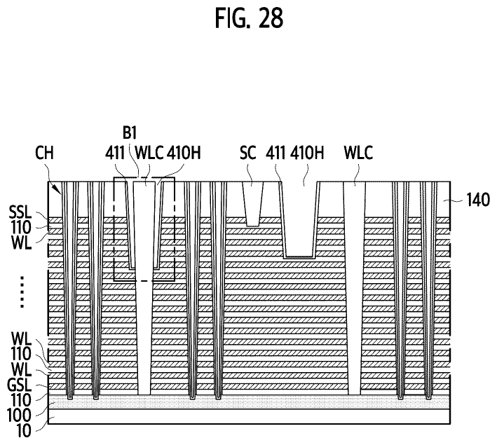

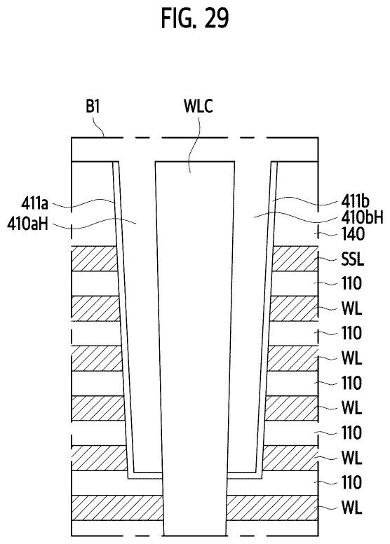

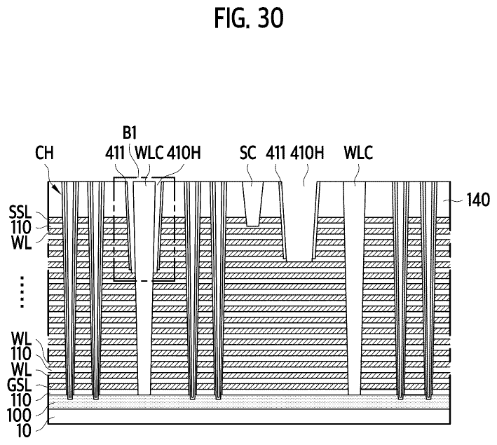

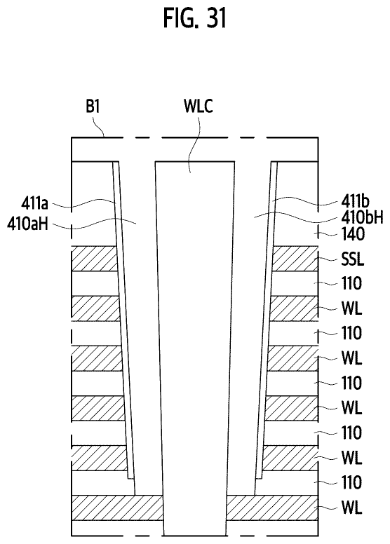

FIGS. 14 through 36 are example drawings illustrating a middle process for describing a method for manufacturing a semiconductor memory device according to example embodiments illustrated in FIG. 9. FIG. 29 is an example drawing illustrating an enlarged view of section B1 of FIG. 28. FIG. 31 is an example drawing illustrating an enlarged view of section B1 of FIG. 30.

Referring to FIG. 14, the cell substrate 100 may be formed on a wafer 10. The mold insulating layer 110 and a mold sacrificial layer 105 may be alternately stacked onto the cell substrate 100, and the first insulating interlayer 140 may be formed on the mold insulating layer 110 and the mold sacrificial layer 105. The mold sacrificial layer 105 may include a material having an etching selectivity with respect to the mold insulating layer 110. For example, the mold insulating layer 110 may include a silicon oxide layer, and the mold sacrificial layer 105 may include a silicon nitride layer.

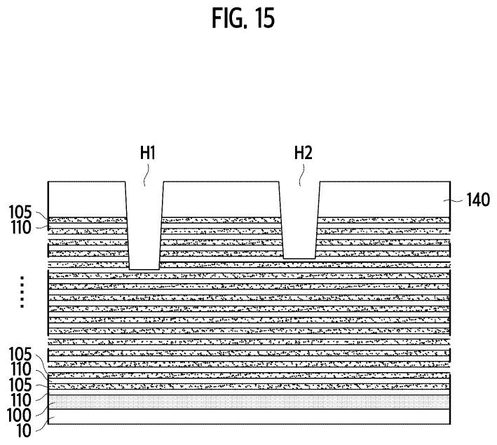

Then, referring to FIG. 15, a first hole H1 and a second hole H2 which pass through at least a portion of the first insulating interlayer 140, the mold insulating layer 110, and the mold sacrificial layer 105, may be formed. The first hole H1 and the second hole H2 may be formed when at least a portion of the first insulating interlayer 140, the mold insulating layer 110, and the mold sacrificial layer 105, is removed. At least a portion of the first insulating interlayer 140, the mold insulating layer 110, and the mold sacrificial layer 105, may be exposed through the first hole H1 and the second hole H2.

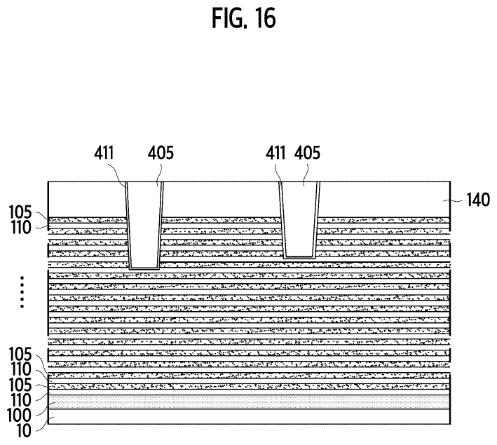

Referring to FIG. 16, the external insulating layer 411 and a first sacrificial filling layer 405 may be formed inside the first hole H1 (of FIG. 15) and the second hole H2 (of FIG. 15). The external insulating layer 411 may be extended along inside walls of the first hole H1 (of FIG. 15) and the second hole H2 (of FIG. 15). The first sacrificial filling layer 405 may fill the first hole H1 (of FIG. 15) and the second hole H2 (of FIG. 15). The first sacrificial filling layer 405 may include a material having an etching selectivity with respect to the external insulating layer 411. For example, the external insulating layer 411 may include a silicon oxide layer, and the first sacrificial filling layer 405 may include a silicon nitride layer.

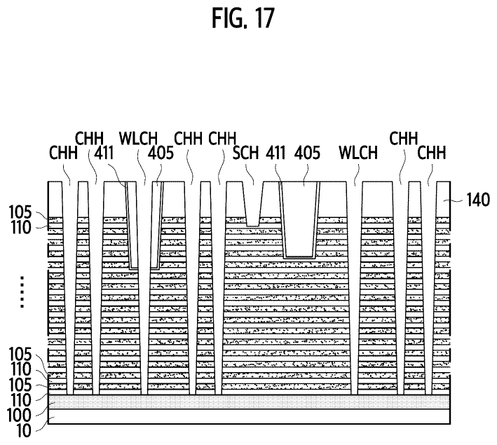

Referring to FIG. 17, a channel hole CHH, a string selection line cutting hole SCH, and a gate cutting hole WLCH may be formed. The channel hole CHH, the string selection line cutting hole SCH, and the gate cutting hole WLCH may pass through the first insulating interlayer 140, the mold insulating layer 110, and the mold sacrificial layer 105, in the first direction D1.

According to example embodiments, the gate cutting hole WLCH may pass through the external insulating layer 411 and the first sacrificial filling layer 405 of the first hole H1 (of FIG. 15). The external insulating layer 411 and the first sacrificial filling layer 405 within the first hole H1 (of FIG. 15) may be separated by the gate cutting hole WLCH. For example, the external insulating layer 411 and the first sacrificial filling layer 405 within the first hole H1 (of FIG. 15) may be separated in the third direction D3 (of FIG. 9) by the gate cutting hole WLCH which is extended in the second direction D2 (of FIG. 9).

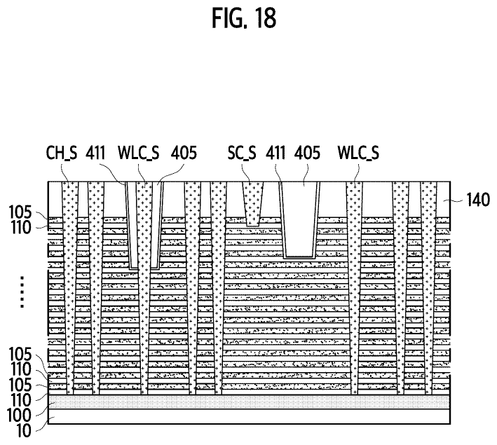

Then, referring to FIG. 18, a channel sacrificial layer CH_S, a string selection line cutting sacrificial layer SC_S, and a gate cutting sacrificial layer WLC_S may be formed. The channel sacrificial layer CH_S, the string selection line cutting sacrificial layer SC_S, and the gate cutting sacrificial layer WLC_S may fill the channel hole CHH (of FIG. 16), the string selection line cutting hole SCH (of FIG. 17), and the gate cutting hole WLCH (of FIG. 16), respectively. For example, the channel sacrificial layer CH_S, the string selection cutting sacrificial layer SC_S, and the gate cutting sacrificial layer WLC_S may include a material having an etching selectivity with respect to the mold insulating layer 110, the mold sacrificial layer 105, and the first sacrificial filling layer 405.

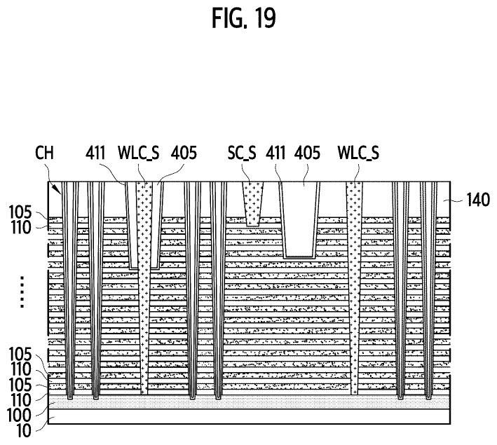

Referring to FIG. 19, the channel structure CH may be formed. The channel sacrificial layer CH_S (of FIG. 18) may be removed, and the channel structure CH may be formed within the channel hole CHH (of FIG. 17). The data storage layer 132 (of FIGS. 7 and 8) and the semiconductor pattern 130 (of FIGS. 7 and 8) may be formed within the channel hole CHH (of FIG. 17).

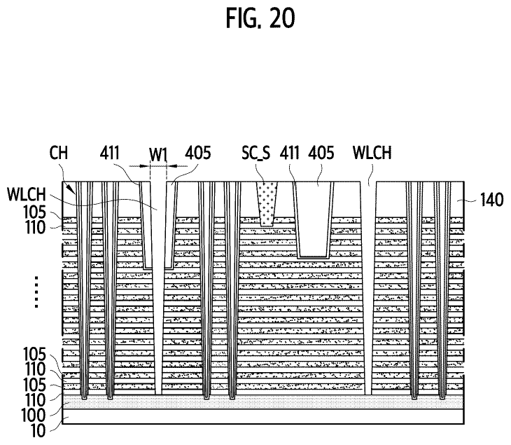

Referring to FIG. 20, the gate cutting sacrificial layer WLC_S (of FIG. 19) may be removed and the gate cutting hole WLCH may be formed. The gate cutting hole WLCH may have a first width W1.

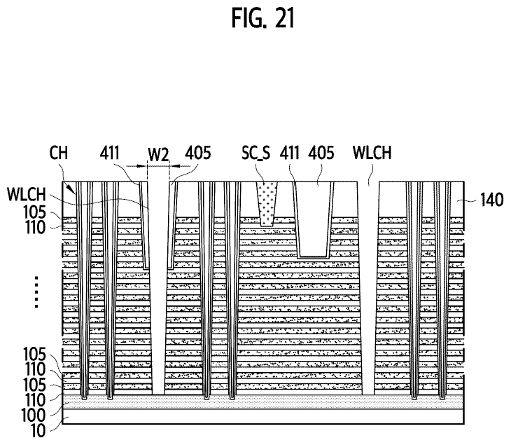

Referring to FIG. 21, the gate cutting hole WLCH may be expanded. The gate cutting hole WLCH may have a second width W2. The second width W2 may be greater than the first width W1 (of FIG. 20). A portion of the first sacrificial filling layer 405, the mold insulating layer 110, and the mold sacrificial layer 105 may be removed within the gate cutting hole WLCH.

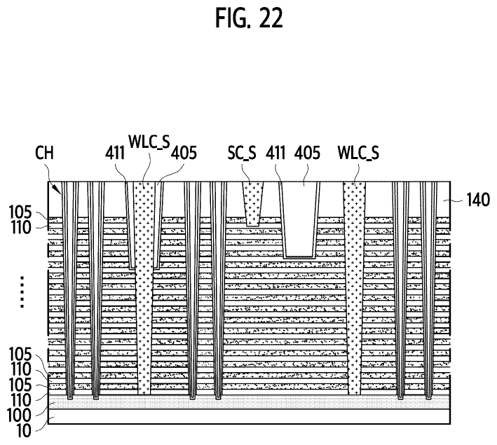

Referring to FIG. 22, the gate cutting sacrificial layer WLC_S may be formed again within the expanded gate cutting hole WLCH (of FIG. 21).

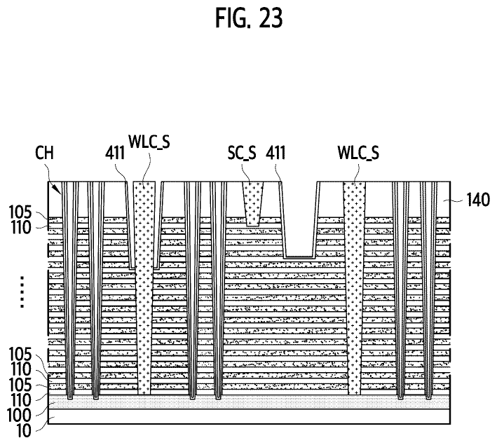

Referring to FIG. 23, the first sacrificial filling layer 405 (of FIG. 22) may be removed. The external insulating layer 411 may be exposed as the first sacrificial layer 405 (of FIG. 22) is removed. A hole may be formed between the gate cutting sacrificial layer WLC_S and the external insulating layer 411 as the first sacrificial filling layer 405 (of FIG. 22) is removed.

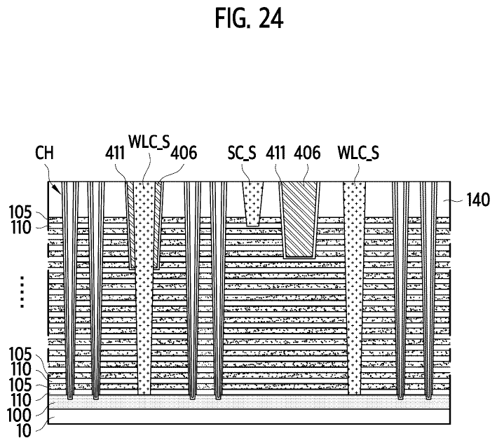

Referring to FIG. 24, a second sacrificial filling layer 406 may be formed. The second sacrificial filling layer 406 may fill a space at which the first sacrificial filling layer 405 (of FIG. 22) is removed. The second sacrificial filling layer 406 may cover the external insulating layer 411 which is exposed as the first sacrificial filling layer 405 (of FIG. 22) is removed. The second sacrificial filling layer 406 may include a material different from that of the first sacrificial filling layer 405 (of FIG. 22). For example, the second sacrificial filling layer 406 may include poly silicon.

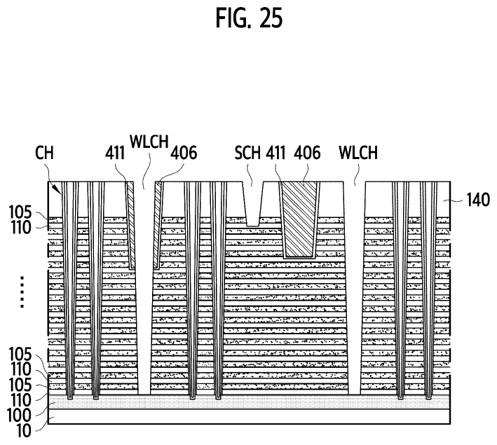

Referring to FIG. 25, the gate cutting hole WLCH may be formed as result of the removal of the gate cutting sacrificial layer WLC_S (of FIG. 24), and the string selection line cutting hole SCH may be formed as a result of the removal of the string selection line cutting sacrificial layer SC_S (of FIG. 24). The mold sacrificial layer 105 may be exposed within the gate cutting hole WLCH.

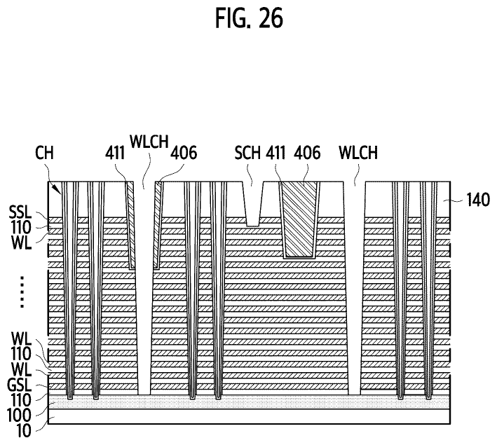

Referring to FIG. 26, the plurality of gate electrodes GSL, WL, and SSL may be formed. The mold sacrificial layer 105 (of FIG. 25) exposed within the gate cutting hole WLCH may be removed. The plurality of gate electrodes GSL, WL, and SSL may be formed in a space at which the mold sacrificial layer 105 (of FIG. 25) is removed.

According to example embodiments, when the mold sacrificial layer 105 (of FIG. 25) is removed and a gap is formed between the mold insulating layers 110, the stacked mold insulating layers 110 may collapse. Since the second sacrificial filling layer 406 within the first hole H1 (of FIG. 15) and the second hole H2 (of FIG. 15) pass through only a portion of the stacked mold insulating layers 110, it may be difficult to support the mold insulating layers 110 when an entire mold sacrificial layers 105 (of FIG. 25) stacked is removed. However, since a plurality of channel structures CH disposed adjacent to the first hole H1 (of FIG. 15) and the second hole H2 (of FIG. 15) are connected to a plurality of mold insulating layers 110 stacked, even when the mold sacrificial layer 105 (of FIG. 25) is removed and a gap is formed between the mold insulating layers 110, the structure of stacked mold insulating layers 110 may be supported stably.

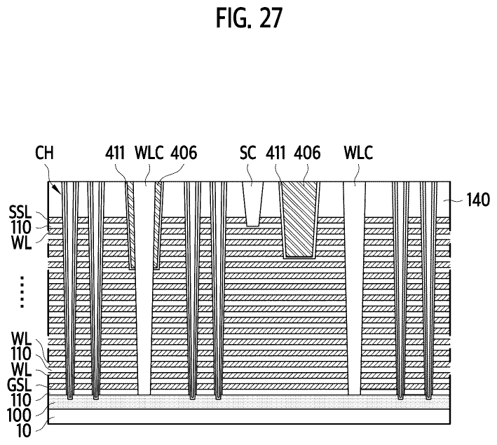

Referring to FIG. 27, the gate cutting structure WLC and the string selection line cutting structure SC may be formed. The gate cutting structure WLC may fill the gate cutting hole WLCH (of FIG. 25). The string selection line cutting structure SC may fill the string selection line cutting hole SCH (of FIG. 26).

Referring to FIG. 28, the second sacrificial filling layer 406 (of FIG. 27) may be removed and a cell gate contact hole 410H may be formed. The external insulating layer 411 may be exposed within the cell gate contact hole 410H. The external insulating layer 411 may cover a bottom surface of the cell gate contact hole 410H.

Referring to FIG. 29, the cell gate contact hole 410H may be separated by the gate cutting structure WLC and a first contact hole 410aH and a second contact hole 410bH may be formed. The first contact hole 410aH may be formed between the first external insulating layer 411a and the gate cutting structure WLC. A first external insulating layer 411a may be exposed within the first contact hole 410aH. The first external insulating layer 411a may cover a bottom surface of the first contact hole 410aH. The second contact hole 410bH may be formed between the second external insulating layer 411b and the gate cutting structure WLC. The second external insulating layer 411b may be exposed within the second contact hole 410bH. The second external insulating layer 411b may cover a bottom surface of the second contact hole 410bH.

Referring to FIGS. 30 and 31, the cell gate contact hole 410H may be extended and the gate electrode (e.g., WL) may be exposed within the cell gate contact hole 410H. For example, the external insulating layer 411 covering the bottom surface of the cell gate contact hole 410H may be removed, and the mold insulating layer 110 exposed within the cell gate contact hole 410H may be further removed. The external insulating layer 411 may not be disposed on the bottom surface of the cell gate contact hole 410H. The first contact hole 410aH may be extended deeper than the first external insulating layer 411a. The second contact hole 410bH may be extended deeper than the second external insulating layer 411b.

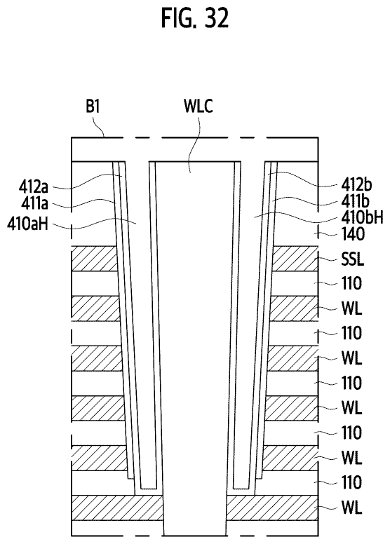

Then, referring to FIG. 32, the first internal insulating layer 412a may be formed within the first contact hole 410aH. The first internal insulating layer 412a may cover the bottom surface of the first contact hole 410aH. The first internal insulating layer 412a may be formed between the first external insulating layer 411a and the gate cutting structure WLC. The second internal insulating layer 412b may be formed within the second contact hole 410bH. The second internal insulating layer 412b may cover the bottom surface of the second contact hole 410bH. The second internal insulating layer 412b may be formed between the second external insulating layer 411b and the gate cutting structure WLC.

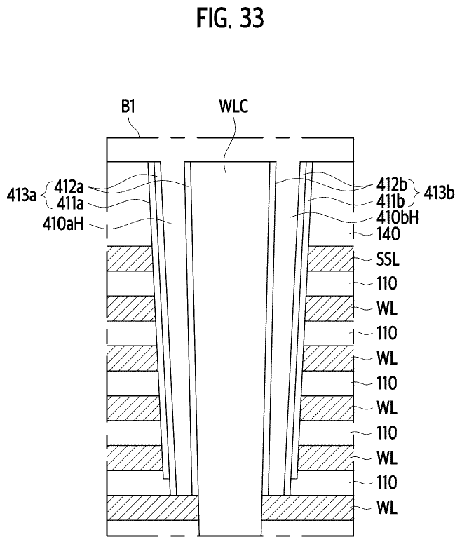

Referring to FIG. 33, a portion of the first internal insulating layer 412a and a portion of the second internal insulating layer 412b may be removed and the second contact hole 410aH may be expanded. The gate electrode (e.g., WL) may be exposed within the first contact hole 410aH and the second contact hole 410bH. The first internal insulating layer 412a may not be disposed on the bottom surface of the first contact hole 410aH. The second internal insulating layer 412b may not be disposed on the bottom surface of the second contact hole 410bH.

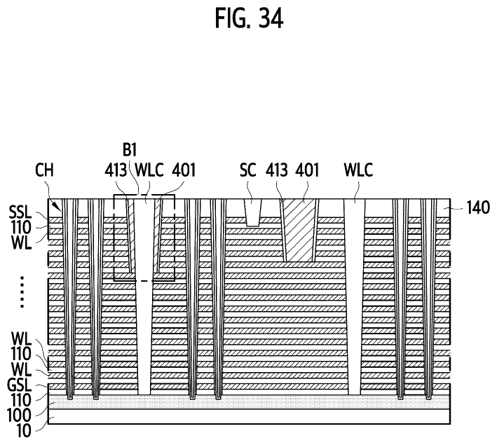

Referring to FIG. 34, the contact conductive layer 401 may be formed. The contact conductive layer 401 may fill the cell gate contact hole 410H (of FIG. 30). The contact conductive layer 401 may cover the contact insulating layer 413.

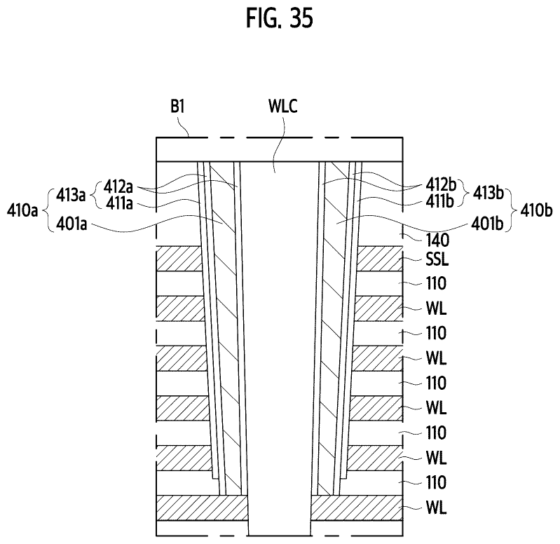

Referring to FIG. 35, the contact insulating layers 413a and 413b may include external insulating layers 411a and 411b and internal insulating layers 412a and 412b.

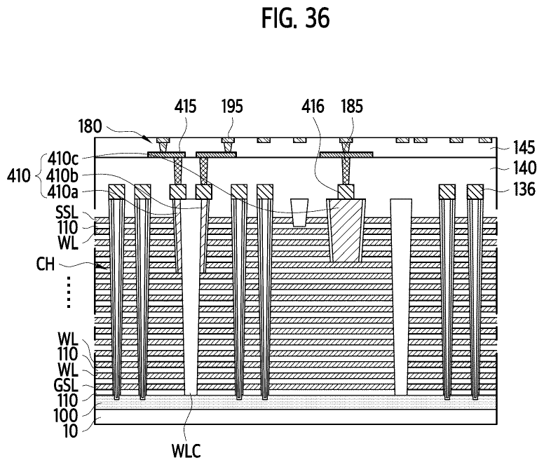

Referring to FIG. 36, the contact pad 416, the contact connection plug 185, and the contact wiring 415 may be formed on the cell gate contact structure 410. The cell wiring structure 180 connected to the contact wiring 415 may be formed on the contact wiring 415. Although not shown in FIG. 36, when the contact wiring 415 is formed, the bit line BL (of FIG. 6) connected to the first channel structure CH1 (of FIG. 6), among channel structures CH, may be formed together.

Referring to FIG. 9, the cell structure CELL may be bonded to the peripheral circuit structure PERI so that the cell wiring structure 180 is connected to the peripheral circuit wiring structure 260.

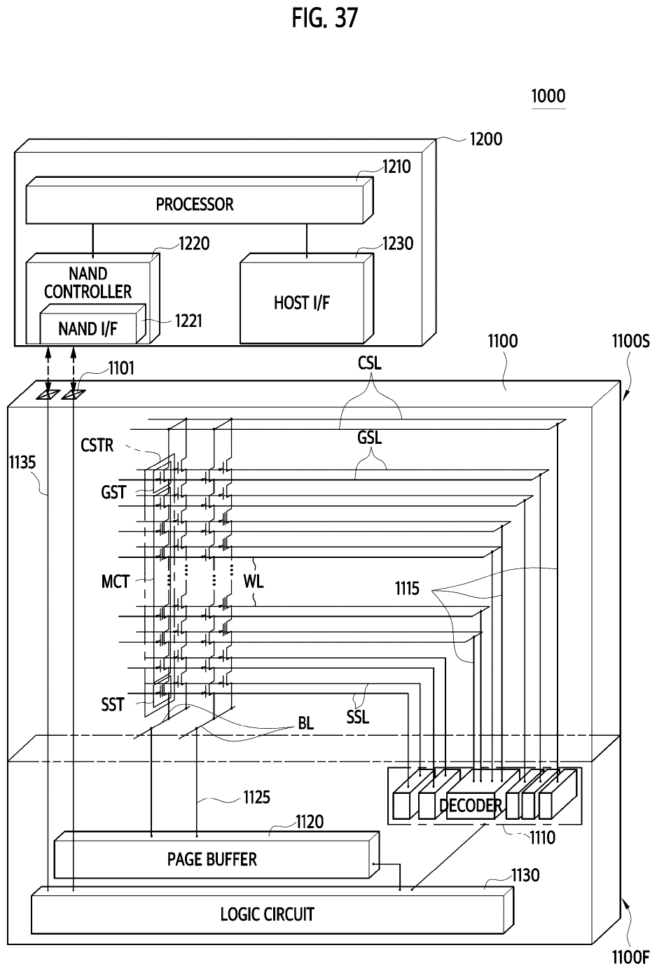

FIG. 37 is an example drawing for describing an electronic system including a semiconductor memory device according to example embodiments.

Referring to FIG. 37, an electronic system 1000 according to example embodiments may include a semiconductor memory device 1100 and a controller 1200 which is electrically connected to the semiconductor memory device 1100. The electronic system 1000 may be a storage device including one or more of semiconductor memory devices 1100 or an electronic device including the storage device. For example, the electronic system 1000 may be a solid-state drive (SSD) device, a universal serial bus (USB), a computing system, a medical device, or a communication device, including one or more semiconductor memory devices 1100.

According to example embodiments, the semiconductor memory device 1100 may be a non-volatile memory device (e.g., NAND flash memory device), and, for example, may be the semiconductor memory device described with reference to FIGS. 1 through 13. The semiconductor memory device 1100 may include a first structure 1100F and a second structure 1100S on the first structure 1100F.

The first structure 1100F may be a peripheral circuit structure including a decoder circuit 1110 (e.g., the row decoder 33 of FIG. 1), a page buffer 1120 (e.g., the page butter 35 of FIG. 1), and a logic circuit 1130 (e.g., the control logic 37 of FIG. 1). The first structure 1100F, for example, may correspond to the peripheral circuit structure PERI described with reference to FIGS. 1 through 13.

The second structure 1100S may include the common source line CSL, the plurality of bit lines BL, and the plurality of cell strings CSTR described with reference to FIG. 2. The cell strings CSTR may be connected to the decoder circuit 1110 through the word line WL, at least one string selection line SSL, and at least one ground selection line GSL. Also, the cell strings CSTR may be connected to the page buffer 1120 through the bit lines BL. The second structure 1100S, for example, may correspond to the cell structures CELL, CELL1 and CELL2 described with reference to FIGS. 1 through 13.

The common source line CSL and cell strings CSTR may be electrically connected to the decoder circuit 1110 through a first connection wiring 1115 which is extended from the first structure 1100F to the second structure 1100S. The bit lines BL may be electrically connected to the page buffer 1120 through a second connection wiring 1125 which is extended from the first structure 1100F to the second structure 1100S.

The semiconductor memory device 1100 may communicate with the controller 1200 through an input/output pad 1101 electrically connected to the logic circuit 1130 (e.g., the control logic 37 of FIG. 1). The input/output pad 1101 may be electrically connected to the logic circuit 1130 through an input/output connection wiring 1135, which is extended from the first structure 1100F to the second structure 1100S. The input/output pad 1101 may correspond to the input/output pad 320 described with reference to FIGS. 1 through 11. The input/output connection wiring 1135 may correspond to the through via structure 420 described with reference to FIGS. 1 through 13.

The controller 1200 may include a NAND controller 1220 and a host interface 1230. According to example embodiments, the electronic system 1000 may include a plurality of semiconductor memory devices 1100, and in this case, the controller 1200 may control the plurality of semiconductor memory devices 1100.

A processor 1210 may control overall operations of the electronic system 1000 which includes the controller 1200. The processor 1210 may operate according to a predetermined firmware, and may access the semiconductor memory device 1100 by controlling the NAND controller 1220. The NAND controller 1220 may include a NAND interface 1221 for processing communication with the semiconductor memory device 1100. Through the NAND interface 1221, a control instruction for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may allow communication between the electronic system 1000 and an external host. When a control instruction is received from the external host through the host interface 1230, the processor 1210 may control the semiconductor memory device 1100 in response to the control instruction.

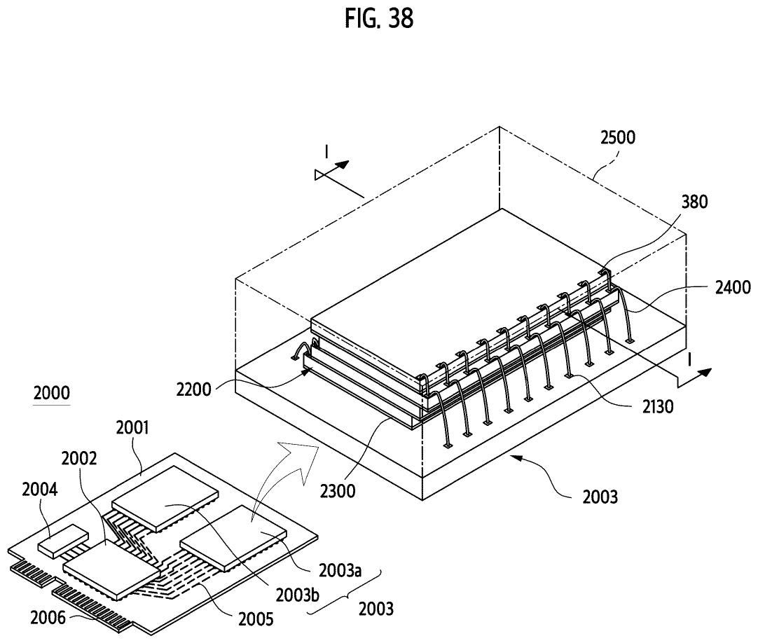

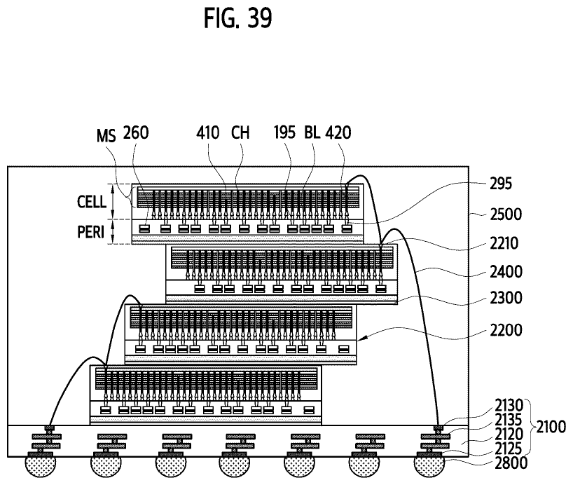

FIG. 38 is an example perspective view for describing an electronic system including a semiconductor memory device according to example embodiments. FIG. 39 is an example drawing illustrating a cross-section taken along line I-I of FIG. 38.

Referring to FIGS. 38 and 39, the electronic system according to example embodiments may include a main substrate 2001, a main controller 2002 mounted to the main substrate 2001, one or more semiconductor packages 2003, and a dynamic random-access memory (DRAM) 2004. The semiconductor package 2003 and the DRAM 2004 may be connected to the main controller 2002 via wiring patterns 1005 formed on the main substrate 2001.

The main substrate 2001 may include a connector 2006 which includes a plurality of pins combined with the external host. The number and arrangement of the plurality of pins on the connector 2006 may be changed based on a communication interface between the electronic system 2000 and the external host. According to example embodiments, the electronic system 2000 may communicate with the external host through one of interfaces such as universal serial bus (USB), peripheral component interconnect express (PCI-Express), serial advanced technology attachment (SATA), and M-PHY for a universal flash storage (UFS). According to example embodiments, the electronic system 2000 may be operated by power supplied by the external host through the connector 2006. The electronic system 2000 may further include a power management integrated circuit (PMIC) that distributes the power supplied by the external host to the main controller 2002 and the semiconductor package 2003.

The main controller 2002 may write data to the semiconductor package 2003 or read data from the semiconductor package 2003, and may increase an operating speed of the electronic system 2000.

The DRAM 2004 may be a buffer memory for reducing speed difference between the semiconductor package 2003, that serves as a data storage space, and the external host. The DRAM 2004 included in the electronic system 2000 may also operate as a type of a cache memory, and may provide a space for temporary data storage in a control operation of the semiconductor package 2003. When the DRAM 2004 is included in the electronic system 2000, the main controller 2002 may further include a DRAM controller for controlling the DRAM 2003 in addition to a NAND controller for controlling the semiconductor package 2003.

The semiconductor package 2003 may include a first semiconductor package 2003a and a second semiconductor package 2003b which are spaced apart from each other. The first semiconductor package 2003a and the second semiconductor package 2003b may each be a semiconductor package including a plurality of semiconductor chips 2200. The first semiconductor package 2003a and the second semiconductor package 2003b may each include a package substrate 2100, semiconductor chips 2200 on the semiconductor package substrate 2100, adhesive layers 2300 disposed on bottom surfaces of the semiconductor chips 2200, a connecting structure 2400 electrically connecting the semiconductor chips 2200 to the package substrate 2100, and a molding layer 2500 disposed on the package substrate 2100 and covering the semiconductor chips 2200 and the connecting structure 2400.

The package substrate 2100 may be a printed circuit board including package upper pads 2130. Each of the semiconductor chips 2200 may include an input/output pad 2210. The input/output pad 2210 may correspond to the input/output pad 1101 of FIG. 37.

The connection structure 2400 may be a bonding wire that electrically connects the input/output pad 2210 and the package upper pads 2130. Accordingly, on each of the first semiconductor package 2003a and the second semiconductor package 2003b, the semiconductor chips 2200 may be electrically connected to each other in a wire bonding manner, and may be electrically connected to the package upper pads 2130 of the package substrate 2100. According to example embodiments, on each of the first semiconductor package 2003a and the second semiconductor package 2003b, the semiconductor chips 2200 may be electrically connected to each other through a connection structure including a through-silicon via (TSV), instead of the connection structure 2400 using the wire bonding manner.

The main controller 2002 and the semiconductor chips 2200 may be included in a single package. According to example embodiments, the controller 2002 and the semiconductor chips 2200 may be mounted on a separate interposer substrate other than the main substrate 2001, and may be connected to each other through wiring lines provided on the interposer substrate.

The package substrate 2100 may be a printed circuit board. The package substrate 2100 may include a package substrate body 2120, the package upper pads 2130 disposed on an upper surface of the package substrate body 2120, lower pads 2125 disposed or exposed on a lower surface of the package substrate body 2120, and internal wirings 2135 that electrically connects the upper pads 2130 to the lower pads 2125 within the package substrate body 2120. The upper pads 2130 may be electrically connected to the connection structures 2400. The lower pads 2125 may be connected to wiring patterns 2005 in the main substrate 2001 of the electronic system 2000 through conductive connectors 2800 as illustrated in FIG. 38.

In the electronic system according to example embodiments, each of the semiconductor chips 2200 may include the cell gate contact structure 410 and the through via structure 420, described with reference to FIG. 3 through 13. For example, the cell gate contact structure 410 and the through via structure 420 may be disposed in the cell array region CAR (of FIG. 6) with the plurality of channel structure CH. The cell gate contact structure 410 and the through via structure 420 may be disposed between the plurality of channel structures CH. The cell gate contact structure 410 and the through via structure 420 may be surrounded by the plurality of channel structures CH. Thicknesses of the mold structure in which the cell gate contact structure 410 and the through via structure 420 are disposed may be equal.

According to example embodiments, it is possible to improve electrical characteristics and integration of a semiconductor memory device.

While the present disclosure has been described in detail in connection with above example embodiments, however, the scope of the present disclosure is not limited thereto and it is to be understood by those skilled in the art that the present disclosure is intended to cover various modifications and equivalent arrangements within the spirit and scope of the appended claims. In addition, the above-described example embodiments may be implemented with some elements thereof removed, and each example embodiment may be implemented.

What is claimed is:

1. A semiconductor memory device comprising:
a mold structure comprising a gate electrode and a mold insulating layer which are alternately stacked in a first direction;
a plurality of channel structures which pass through the mold structure in the first direction;
a cell gate contact structure which passes through at least a portion of the mold structure, overlaps with the plurality of channel structures in the second direction and the third direction, and is connected to the gate electrode;
a plurality of bit lines disposed on one side of the cell gate contact structure, spaced apart from each other in a second direction crossing the first direction, extended in a third direction crossing the first direction and the second direction, and connected to at least one of the plurality of channel structures; and
a contact wiring which is extended in the third direction, spaced apart from the plurality of bit lines in the second direction, and connected to the cell gate contact structure,
wherein the plurality of bit lines include first and second bit lines which are more adjacent to the contact wiring in the second direction than other bit lines among the plurality of bit lines,
the first bit line is disposed between the contact wiring and the second bit line, and
a first distance between the contact wiring and the first bit line in the second direction is greater than a second distance between the first bit line and the second bit line in the second direction.

2. The semiconductor memory device of claim 1, wherein the first distance is more than twice the second distance.

3. The semiconductor memory device of claim 1, wherein a thickness in the first direction of a region of the mold structure in which the cell gate contact structure is disposed and a thickness in the first direction of a region of the mold structure in which the plurality of channel structures are disposed are equal.

4. The semiconductor memory device of claim 1, wherein vertical levels of the plurality of bit lines and a vertical level of the contact wiring in the first direction are equal.

5. The semiconductor memory device of claim 1, wherein an extension length of the contact wiring in the third direction is smaller than extension lengths of the plurality of bit lines in the third direction.

6. The semiconductor memory device of claim 1, further comprising a gate cutting structure which passes through the mold structure in the first direction and is extended in the second direction.

7. The semiconductor memory device of claim 6, wherein the cell gate contact structure comprises a first contact structure and a second contact structure which are spaced apart in the third direction with the gate cutting structure in between, and
the first contact structure and the second contact structure are individually extended along side walls of the gate cutting structure, which are disposed in the third direction.

8. The semiconductor memory device of claim 7, wherein the gate electrode which is connected to the first contact structure and the gate electrode which is connected to the second contact structure have an equal vertical level in the first direction.

9. The semiconductor memory device of claim 7, wherein the cell gate contact structure further comprises a third contact structure which is spaced apart from the gate cutting structure in the third direction.

10. The semiconductor memory device of claim 9, wherein a vertical level in the first direction of the gate electrode which is connected to the third contact structure is different from a vertical level in the first direction of the gate electrode which is connected to the first contact structure and the second contact structure.

11. The semiconductor memory device of claim 9, wherein a width of the first contact structure and a width of the second contact structure in the third direction are smaller than a width of the third contact structure.

12. The semiconductor memory device of claim 7, wherein the first contact structure comprises:
a first contact conductive layer which is in contact with the gate electrode;
a first inner insulating layer which surrounds the first contact conductive layer and is extended along a side wall of the gate cutting structure; and
a first outer insulating layer which surrounds the first inner insulating layer and is disposed between the mold structure and the first inner insulating layer.

13. The semiconductor memory device of claim 1, wherein the plurality of channel structures comprise:
a first channel structure connected to one of the plurality of bit lines; and
a second channel structure not connected to the plurality of bit lines, and
the second channel structure overlaps with the cell gate contact structure in the third direction.

14. The semiconductor memory device of claim 1, wherein a signal level applied to the first bit line is different from signal levels applied to bit lines other than the first bit line among the plurality of bit lines.

15. A semiconductor memory device comprising:
a mold structure comprising a gate electrode and a mold insulating layer which are alternately stacked in a first direction;
a plurality of channel structures which pass through the mold structure in the first direction;
a plurality of bit lines spaced apart from each other in a second direction crossing the first direction, extended in a third direction crossing the first direction and the second direction, and connected to at least one of the plurality of channel structures;
a cell gate contact structure which passes through at least a portion of the mold structure, disposed between the plurality of channel structures, and is connected to the gate electrode; and
a contact wiring which is extended in the third direction, spaced apart from the plurality of bit lines in the second direction, and connected to the cell gate contact structure,
wherein the cell gate contact structure includes a plurality of contact structures spaced apart and disposed in the second direction,
at least one of the plurality of bit lines is disposed between the plurality of contact structures in the second direction, and
vertical levels of the plurality of bit lines and a vertical level of the contact wiring in the first direction are equal.

16. The semiconductor memory device of claim 15, wherein the plurality of bit lines are disposed on one side of the cell gate contact structure, and include first and second bit lines which are more adjacent to the contact wiring in the second direction than other bit lines among the plurality of bit lines,
the first bit line is disposed between the contact wiring and the second bit line, and
a first distance between the contact wiring and the first bit line in the second direction is more than a second distance between the first bit line and the second bit line in the second direction.

17. The semiconductor memory device of claim 15, further comprising a gate cutting structure which passes through the mold structure in the first direction and is extended in the second direction,
wherein the cell gate contact structure comprises a first contact structure and a second contact structure which are spaced apart in the third direction with the gate cutting structure in between and are individually extended along side walls of the gate cutting structure, which are disposed in the third direction.

18. The semiconductor memory device of claim 17, wherein a width of the gate cutting structure in the third direction is greater than a width of one of the plurality of the channel structures.

19. The semiconductor memory device of claim 15, wherein a thickness of the mold structure in the first direction is consistent.

20. A semiconductor memory device comprising:
a cell structure in which a plurality of memory cells are disposed; and
a peripheral circuit structure disposed to the cell structure in a first direction,
wherein the cell structure comprises:
a mold structure comprising a gate electrode and a mold insulating layer which are alternately stacked in the first direction;
a plurality of channel structures which pass through the mold structure in the first direction and form the plurality of memory cells;
a plurality of bit lines which are spaced apart from each other in a second direction crossing the first direction, extended in a third direction crossing the first direction and the second direction, and connected to at least one of the plurality of channel structures;
a cell gate contact structure which passes through at least a portion of the mold structure and is connected to the gate electrode; and
a contact wiring which is extended in the third direction, spaced apart from the plurality of bit lines in the second direction, and connected to the cell gate contact structure,
the cell structure comprises a first cell region and a second cell region in which the cell gate contact structure is disposed and which do not overlap with each other in the second direction,
the peripheral circuit structure comprises:
a first peripheral circuit region which overlaps with the first cell region in the first direction;
a second peripheral circuit region which overlaps with the second cell region in the first direction;
a third peripheral circuit region which is disposed in the second direction with the first peripheral circuit region and is disposed in the third direction with the second peripheral circuit region; and
a fourth peripheral circuit region which is disposed in the second direction with the second peripheral circuit region, is disposed in the third direction with the first peripheral circuit region, and does not overlap with the third peripheral circuit region in the second direction and the third direction,
the first peripheral circuit region and the second peripheral circuit region comprise a row decoder circuit which is connected to the cell gate contact structure, and
the third peripheral circuit region and the fourth peripheral circuit region comprise a page buffer circuit connected to the plurality of bit lines.
